(19) United States
(12) Patent Application Publication
(10) Pub. No.: US 2007/0082140 A1
(43) Pub. Date: Apr. 12, 2007

(54) Manufacturing method of laminated body, manufacturing organic device and organic thin-film solar cell using same, and organic device and organic thin-film solar cell

(76) Inventors: Hiroyuki Suzuki, Tokyo (JP); Koujiro Ohkawa, Tokyo (JP)

Correspondence Address: SEYFARTH SHAW LLP, 131 S. DEARBORN ST., SUITE2400, CHICAGO, IL, 60603-5803, US

(21) Appl. No.: 11/389,900

(22) Filed: Mar. 27, 2006

(30) Foreign Application Priority Data
Mar. 28, 2005 (JP) 2005-093307
Sep. 6, 2005 (JP) 2005-258577

(51) Int. Cl. B05D 1/36

(52) U.S. Cl. 427/402

(57) ABSTRACT

A main object of the invention is to provide a manufacturing method of a laminated body which can make the following matters possible: when two or more layers are formed to be laminated by coating, constituents of an underlying layer are restrained from eluting into a solvent in a coating-solution for forming an upper layer; and the plural layers are laminated without restricting the kind of the solvent used in the upper layer forming coating-solution or constituent materials of the upper layer. To resolve the object, the present invention provides a manufacturing method of a laminated body, comprising an underlying layer forming step of coating an underlying layer forming coating-solution comprising a polymer material, thereby forming an underlying layer, and an upper layer forming step of coating an upper layer forming coating-solution on the underlying layer.

### BACKGROUND OF THE INVENTION

1. Field of the Invention

The present invention relates to a manufacturing method of a laminated body wherein two or more layers are formed to be laminated by coating, in particular, a manufacturing method of an organic device, such as an organic thin-film solar cell or an organic electroluminescent element, using the laminated body manufacturing method.

2. Description of the Related Art

Attention has been paid to organic devices which are each formed by laminating plural layers by coating. Coating has advantages of requiring only simpler facilities than vacuum film-forming methods such as vapor deposition or sputtering, and making it possible to shorten the process time, and other advantages. However, when an organic device is formed by laminating plural layers by coating, in many cases a coating-solution is used which is prepared by dissolving or dispersing constituent materials of each of the layers into a solvent. Thus, there is caused a problem that when a solvent in a coating-solution for forming an upper layer contacts a lower layer, constituents of the lower layer elute out. Furthermore, when the constituents of the lower layer elute out, the constituents are incorporated into a portion of the upper layer which contacts the lower layer so as to cause a problem that each of the upper and the lower layers does not fulfill its function sufficiently.

In general, therefore, as the solvent for the upper layer forming coating solution, there is used a solvent wherein the constituents of the lower layer are not dissolved at all (see, for example, C. W. Tang, “Two-layer organic photovoltaic cell”, Applied Physics Letters, vol. 48, No. 2, pp. 183-185 (1986)).

In the field of organic devices such as organic thin-film solar cells and organic electroluminescent elements, an organic layer can be formed by coating a coating-solution wherein an organic semiconductor material is dissolved or dispersed in a solvent. When such organic layers are laminated onto each other to form an organic semiconductor layer, the kind of the solvent, which can be used in the coating-solution, is restricted as described above. Accordingly, there is a limitation to the selection of constituent materials of each of the organic layers in the organic semiconductor layer, or the number of the laminated organic layers. It is therefore difficult to use a preferred material or a preferred layer structure for the improvement in performances of elements.

### SUMMARY OF THE INVENTION

The present invention has been made in consideration of the above-mentioned problems. Thus, a main object of the invention is to provide a manufacturing method of a laminated body which can make the following matters possible: when two or more layers are formed to be laminated by coating, constituents of an underlying layer are restrained from eluting into a solvent in a coating-solution for forming an upper layer; and the plural layers are laminated without restricting the kind of the solvent used in the upper layer forming coating-solution or constituent materials.

To achiever the object, the present invention provides a manufacturing method of a laminated body, comprising an underlying layer forming step of coating an underlying layer forming coating-solution comprising a polymer material to form an underlying layer, and an upper layer forming step of coating an upper layer forming coating-solution on the underlying layer to form an upper layer.

In the invention, the underlying layer comprises the polymer material. Consequently, the underlying layer has an improved solvent resistance. Thus, when the upper layer forming coating-solution is coated onto the underlying layer in the upper layer forming step, the polymer material can be restrained from eluting out from the underlying layer. Unlike the prior art, the invention is not a method of using a difference in solubility in a solvent between constituent materials of an underlying layer and constituent materials of an upper layer to laminate the layers; therefore, the invention has an advantage that the kind of the solvent used in the upper layer forming coating-solution and the constituent materials of the upper layer are not restricted. This makes it possible to easily laminate plural layers which cannot be laminated by coating in the prior art.

In the above-mentioned invention, it is preferable that the weight-average molecular weight of the polymer material is 100,000 or more. When the weight-average molecular weight of the polymer material is within the above-described range, it is possible to effectively restrain the polymer material in the underlying layer from being dissolved into the solvent in the upper layer forming coating-solution.

Further, in the present invention, it is preferable that a solvent in the upper layer forming coating solution has compatibility with a solvent in the underlying layer forming coating-solution. In the prior art, a solvent compatible with the solvent used in an underlying layer forming coating-solution cannot be used since the former solvent has affinity with the constituent materials of the underlying layer. In the invention, however, the polymer material in the underlying layer is restrained from eluting into the solvent in the upper layer forming coating-solution, as described above; therefore, even such a solvent can be used. Thus, the advantageous effects of the invention are remarkably exhibited.

Furthermore, in the present invention, the polymer material is preferably a high molecular organic semiconductor material and the upper layer forming coating-solution preferably comprises the high molecular organic semiconductor material. This makes it possible to use the laminated body manufacturing method of the invention as a manufacturing method of an organic device such as an organic thin-film solar cell or an organic electroluminescent element.

At the time, the high molecular organic semiconductor material is preferably an electroconductive polymer material. Since the electroconductive polymer material has a developed π conjugated system in its polymeric main chain, the material is basically advantageous in transporting electric charges in the direction of the main chain. The polymer material also has an advantage that the material can easily be formed into a film by coating and a large-area organic device can be manufactured from this material at low costs without requiring expensive facilities.

Moreover, the present invention provides a manufacturing method of an organic device comprising a substrate, a first electrode layer formed on the substrate, an organic semiconductor layer formed on the first electrode layer and comprising at least two organic layers, and a second electrode layer formed on the organic semiconductor layer, wherein the manufacturing method of a laminated body mentioned above is used to form the organic semiconductor layer.

In the invention, the above-mentioned laminated body manufacturing method is used; it is therefore possible that when the organic semiconductor layer, which comprises at least two or more layer, is formed, the polymer material in the underlying layer is restrained from eluting into the solvent in the upper layer forming coating-solution. Additionally, the kind of the organic semiconductor material and that of the solvent used in the upper layer forming coating-solution are not limited; it is therefore possible to use an organic semiconductor material having a desired nature. This makes it possible to laminate organic layers each having a desired function as an organic semiconductor layer and manufacture an organic device having a high performance.

Still further, the invention provides a manufacturing method of an organic thin-film solar cell, using the manufacturing method of an organic device mentioned above, wherein the organic semiconductor layer of the organic device has two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.

In the invention, this organic device manufacturing method is used; it is therefore to restrain the p type organic semiconductor material or the n type organic semiconductor material from being mingled and incorporated into the interface between any two of the hole transporting layer(s), the electron transporting layer(s) and the electron hole transporting layer(s) in the organic semiconductor layer. As a result, each of the hole transporting layer(s), the electron transporting layer(s) and the electron hole transporting layer(s) can be made to exhibit its function sufficiently. Furthermore, the hole transporting layer(s), the electron transporting layer(s) and the electron hole transporting layer(s) can be formed by use of one or more p type and/or n type organic semiconductor materials each having a desired nature. This makes it possible to manufacture an organic thin-film solar cell having a high performance through simple steps.

The present invention also provides an organic device, comprising a substrate, a first electrode layer formed on the substrate, an organic semiconductor layer formed on the first electrode layer and comprising a first organic layer comprising a high molecular organic semiconductor material having a weight-average molecular weight of 100,000 or more and a second organic layer formed on the first organic layer, and a second electrode layer formed on the organic semiconductor layer.

In the invention, the first organic layer comprises the high molecular organic semiconductor material, which has the given weight-average molecular weight; therefore, when the second organic layer is formed, the organic semiconductor material in the first organic layer can be restrained from eluting into the solvent in a coating-solution for forming the second organic layer. Thus, the organic semiconductor material can be restrained from being mingled and incorporated into the interface between the first and second organic layers. Moreover, since the organic semiconductor material used in the second organic layer and the solvent used are not limited, an organic semiconductor material having a desired nature can be used. Accordingly, the organic device can be manufactured to have a high performance.

The invention further provides an organic thin-film solar cell comprising the organic device mentioned above, wherein the organic semiconductor layer of the organic device has two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.

Since the organic thin-film solar cell of the invention is a cell wherein the above-mentioned organic device is used, the cell has the above-mentioned advantages and makes it possible to improve the photoelectric conversion efficiency.

In the invention, plural layers, which cannot be laminated by applying in the prior art, can easily be laminated. According to this, the invention produces, for example, an advantageous effect of improving the performance of an organic device, and the like.

### BRIEF DESCRIPTION OF THE DRAWINGS

FIG. 1 is a schematic sectional view illustrating an example of the organic thin-film solar cell of the invention;

FIG. 2 is a schematic sectional view illustrating another example of the organic thin-film solar cell of the invention;

FIG. 3 is a schematic sectional view illustrating still another example of the organic thin-film solar cell of the invention;

FIG. 4 is a schematic sectional view illustrating an example of the organic device of the invention.

FIG. 5 is a schematic sectional view illustrating another example of the organic device of the invention.

### DESCRIPTION OF THE PREFERRED EMBODIMENT

The following will describe, in detail, the manufacturing method of a laminated body, the manufacturing methods of an organic device and an organic thin-film solar cell using the same, and the organic device and the organic thin-film solar cell which are each produced according to the invention.

A. Manufacturing Method of a Laminated Body

First, the laminated body manufacturing method of the invention is described. The method of manufacturing the laminated body of the invention comprises an underlying layer forming step of coating an underlying layer forming coating-solution comprising a polymer material to form an underlying layer, and an upper layer forming step of coating an upper layer forming coating-solution on the underlying layer to form an upper layer.

In the invention, the underlying layer comprises the polymer material; accordingly, the solvent resistance is improved. Thus, when the upper layer forming coating-solution is coated onto the underlying layer in the upper layer forming step, the polymer material can be restrained from eluting out from the underlying layer. This makes it possible to prevent the following: the constituent materials of the underlying layer and the upper layer are mingled with each other so that the function of each of the layers is hindered. Besides, the polymer material from the underlying layer is restrained from eluting out or the like; it is therefore possible to suppress the generation of unevenness in the film thickness and make the underlying layer and the upper layer even.

For example, in the case of using the laminated body manufacturing method of the invention to form an organic semiconductor layer in an organic device such as an organic thin-film solar cell or an organic electroluminescent element, each of organic layers contained in the organic semiconductor layer can be made to exhibit its function sufficiently. Moreover, plural organic layers can be evenly formed without generating unevenness in film thickness; thus, a resistance barrier in the interface of the organic semiconductor layer and an electrode layer adjacent thereto can be decreased and further a short-circuit can be prevent from being generated between the electrode layer and a counter electrode layer.

Unlike the prior art, the invention is not a method of using a difference in solubility in a solvent between constituent materials of an underlying layer and constituent materials of an upper layer to laminate the layers; therefore, the invention has an advantage that the kind of the solvent used in the upper layer forming coating-solution and the constituent materials of the upper layer are not restricted. This makes it possible to easily laminate plural layers which cannot be laminated by coating in the prior art.

Accordingly, the laminated body manufacturing method of the invention is particularly useful as a manufacturing method of an organic device, such as an organic thin-film solar cell or an organic electroluminescent element using an organic semiconductor material.

The laminated body manufacturing method of the invention is not particularly limited if the method comprises the above-mentioned underlying layer forming step and upper layer forming step. The method can be classified into the following two preferred embodiments in accordance with the kind of the polymer material comprised in the underlying layer forming coating-solution. In the first embodiment, the weight-average molecular weight of the polymer material is 100,000 or more. Specifically, the underlying layer forming step in the invention is a step of coating an underlying layer forming coating-solution comprising a polymer material having a weight-average molecular weight of 100,000 or more, thereby forming an underlying layer. In the second embodiment, the polymer material is an insulating resin material. Specifically, the underlying layer forming step in the invention is a step of coating an underlying layer forming coating-solution comprising an insulating resin material, thereby forming an underlying layer.

The embodiments of the laminated body manufacturing method of the invention will be separately described below.

1. First Embodiment

The first embodiment of the laminated body manufacturing method of the invention comprises an underlying layer forming step of coating an underlying layer forming coating-solution comprising a polymer material having a weight-average molecular weight of 100,000 or more to form an underlying layer, and an upper layer forming step of coating an upper layer forming coating-solution on the underlying layer to form an upper layer.

In the present embodiment, the underlying layer comprises the polymer material, which has a weight-average molecular weight of 100,000 or more; therefore, when the upper layer forming coating-solution is coated on underlying layer in the upper layer forming step, the polymer material can be restrained from eluting out from the underlying layer.

The following will describe each of the steps in the laminated body manufacturing method of the present embodiment.

(1) Underlying Layer Forming Step

The underlying layer forming step in the embodiment is a step of coating an underlying layer forming coating-solution comprising a polymer material having a weight-average molecular weight of100,000 or more, thereby forming an underlying layer. The underlying layer forming coating-solution and the method for forming the underlying layer will be described below.

(i) Underlying Layer Forming Coating-Solution

The underlying layer forming coating-solution used in the embodiment is a coating-solution comprising a polymer material having a weight-average molecular weight of 100,000 or more. Usually, the coating-solution is prepared by dissolving or dispersing this polymer material into a solvent. The polymer material, which has the given weight-average molecular weight, and the solvent will be described below.

(Polymer Material with the Given Weight-Average Molecular Weight)

About the polymer material used in the embodiment, the weight-average molecular weight thereof is 100,000 or more, preferably 300,000 or more, and most preferably 500,000 or more. The weight-average molecular weight is preferably 5,000,000 or less, more preferably 3,000,000 or less. If the weight-average molecular weight of the polymer material is too small, the polymer material may be dissolved in the solvent in the upper layer forming coating-solution. Conversely, if the weight-average molecular weight of the polymer material is too large, the viscosity of the underlying layer forming coating-solution becomes high so that an evenly coated film may not be formed easily.

The weight-average molecular weight is a value measured by gel permeation chromatography (GPC). Conditions for the measurement are as follows:
Measuring column: HF-2002 manufactured by SHOWA DENKO K. K., styrene-divinylbenzene copolymer
Detector: Differential refractive index detector (RI), RID-6A, manufactured by Shimadzu Corporation, and Ultraviolet ray absorbing detector, SPD-10A manufactured by Shimadzu Corporation, measuring wavelength 254 nm
Measuring conditions: Mobile phase chloroform,
   Flow rate 3 ml/min., and
   Injecting method=injection of 2 ml with a syringe.

The polymer material is appropriately selected in accordance with the usage of the laminated body produced by the invention. For example, a polymer material having various functions is used. In the embodiment, a high molecular organic semiconductor material is particularly preferable. The laminated body wherein the organic semiconductor material is used can be applied to an organic device such as an organic electroluminescent element or an organic thin-film solar cell. Since the organic semiconductor material can be formed into a film by a relatively-low temperature process, the material can be formed into a film on, for example, a plastic film. The material is light and excellent in flexibility, and thus an organic device, which is not broken easily, can be made therefrom. Furthermore, the organic semiconductor material can easily be formed into a film by coating, and thus a large-area organic device can be manufactured at low costs without requiring expensive facilities. Additionally, the organic semiconductor material is rich in kinds thereof and further the property thereof can be varied by changing the molecular structure, and thus an organic device having a desired function can be obtained.

The high molecular organic semiconductor material used in the embodiment is not particularly limited if the material has the given weight-average molecular weight. Examples thereof include high molecular p type organic semiconductor materials, high molecular n type organic semiconductor material, and high molecular organic semiconductor materials which are each doped with an electron-donating compound or an electron-accepting compound.

The high molecular p type organic semiconductor material is not particularly limited as long as the material is a material having a function as an electron donor. Examples thereof include a polyphenylene, a polyphenylenevinylene, a polysilane, a polythiophene, a polycarbazole, a polyvinylcarbazole, a porphyrin, a polyacetylene, a polypyrrole, a polyaniline, a polyfluorene, a polyvinylpyrene, a polyvinylanthracene, and derivatives thereof and copolymers thereof; and phthalocyanine-containing polymers, carbazole-containing polymers, and electroconductive polymer material such as organic metal polymers. These high molecular p type organic semiconductor materials can be used alone or in combination of two or more thereof.

Of the above, the following are preferably used; thiophene-fluorene copolymers, polyalkylthiophene, phenyleneethynylene-phenylenevinylene copolymers, phenyleneethynylene-thiophene copolymers, phenyleneethynylene-fluorene copolymers, fluorene-phenylenevinylene copolymers, thiophene-phenylenevinylene copolymers, and so on. These give an appropriate energy level difference with respect to many n type organic semiconductor materials.

For example, a process for synthesizing a phenyleneethynylene-phenylenevinylene copolymer (poly[1,4-phenyleneethynylene-1,4-(2,5-dioctadodecylox yphenylene)-1,4-phenyleneethene-1,2-diyl-1,4-(2,5-dioc tadodecyloxyphenylene)ethene-1,2-diyl]) is described in detail in Macromolecules, 35, 3825 (2002) or Mcromol. Chem. Phys., 202, 2712 (2001).

In the embodiment, electroconductive polymer materials, out of the above-mentioned high molecular p type organic semiconductor materials, are preferably used.

Electroconductive polymers are each a π conjugated polymer, and are each made of a π conjugated system, wherein carbon-carbon double or triple bonds, or double or triple bonds containing a hetero atom are alternately connected to single bonds, and exhibit semiconductor property. The electroconductive polymer materials have, in the polymeric main chain thereof, a developed π conjugated system; therefore, the materials are advantageous in transporting electric charges in the main chain direction. Besides, the electroconductive polymer materials can each be formed into a film easily by coating using a coating-solution wherein the material is dissolved or dispersed in a solvent; therefore, the materials have an advantage that a large-area organic device can be manufactured at low costs without requiring expensive facilities.

The high molecular n type organic semiconductor material is not particularly limited as long as the material is a material having a function as an electron acceptor. Examples thereof include a polyphenylenevinylene, a polyfluorene and derivatives thereof and an electroconductive polymer material such as copolymers thereof; or carbon nanotubes, fullerene derivatives, a CN or CF₃ group containing polymer, and —CF₃substituted polymers thereof. Specific examples of the polyphenylenevinylene derivatives include a CN-PPV (poly[2-methoxy-5-(2′-ethylhexyloxy)-1,4-(1-cyanovinylene)phenylene]), and a MEH-CN-PPV (poly[2-methoxy-5-(2′-ethylhexyloxy)-1,4-(1-cyanovinylene)phenylene]). These high molecular n type organic semiconductor materials can be used alone or in combination of two or more thereof.

In the embodiment, electroconductive polymer materials, out of the above-mentioned high molecular n type organic semiconductor materials, are preferably used since the materials have the same advantages as described above.

Examples of the high molecular organic semiconductor materials each doped with an electron-donating compound or an electron-accepting compound include the above-mentioned high molecular p type or n type organic semiconductor materials each doped with an electron-donating compound or an electron-accepting compound. Electroconductive polymer materials each doped with an electron-donating compound or an electron-accepting compound are particularly preferable for the following reasons: the electroconductive polymer materials have, in the polymeric main chain thereof, a developed π conjugated system so as to produce a basic advantage in transporting electric charges in the main chain direction; and when the materials are doped with an electron-donating compound or an electron-accepting compound, electric charges are generated in the π conjugated main chain so that the electric conductivity can be largely increased.

The electron-donating compound for the doping may be a Lewis base, such as an alkali metal or an alkaline earth metal, for example, Li, K, Ca or Cs. The Lewis base acts as an electron donor. The electron-accepting compound for the doping may be a Lewis acid such as FeCl₃ (III), AlCl₃, AlBr₃, AsF₆ or a halogen compound. The Lewis acid acts as an electron acceptor.

As the method for making the above-mentioned polymer material into a higher molecular weight to have the given weight-average molecular weight, an ordinarily used method can be adopted. Examples thereof include an oxidation polymerization, an electrolytic polymerization, a vapor deposition polymerization, a chemical polymerization, and an energy radiating polymerization. The higher-degree polymerizing method is appropriately selected in accordance with tie kind of the polymer material. For example, about the method for making a polyphenylene vinylene (MDMO-PPV, poly(2-methoxy-5-(3′,7′-dimethyloctyloxy)-1-4-phenylenevinylene)) into a higher molecular weight, a method described in Thin Solid Films, 363, 98-101 (2002) can be referred to.

(Solvent)

The solvent used in the underlying layer forming coating-solution is not particularly limited if the solvent is a solvent wherein the above-mentioned polymer material can be dissolved or dispersed. Examples thereof include ketone-based solvents, alcohol-based solvents, ester-based solvents, ether-based solvents, aromatic hydrocarbon-based solvents, halogenated aliphatic or aromatic hydrocarbon-based solvents, and mixtures thereof. Specific examples thereof include a cyclohexanone, an acetone, a methyl ethyl ketone, a methanol, an ethanol, abutanol, an amyl alcohol, a butyl acetate, a dibutyl ether, a tetrahydrofuran, a toluene, a xylene, a chlorobenzene, a carbon tetrachloride, a chloroform, a methylene chloride, and a trichloroethylene. These solvents may be used alone or two or more kinds in combination.

(Different Constituent Material of the Underlying Layer)

The underlying layer forming coating-solution used in the embodiment is not particularly limited if the coating-solution comprises the above-mentioned polymer material. Thus, the coating-solution may comprise a different constituent material besides the polymer material. The different constituent material, which can be used at this time, is appropriately selected in accordance with the usage of the laminated body manufactured by the invention, and is preferably a high molecular material. If the different constituent material is a low molecular material, the material may elute into the upper layer forming coating-solution, or the like. The weight-average molecular weight of the high molecular material is not particularly limited, and may be smaller than the weight-average molecular weight of the above-mentioned polymer material. It appears that even if the weight-average molecular weight of the high molecular material is smaller than that of the above-mentioned polymer material in the embodiment, the high molecular material hardly elutes into the upper layer forming coating-solution, or the like. The reason therefor is unclear, but the incorporation of the above-mentioned polymer material would cause the constituent materials in the underlying layer not to elute out as the whole of the underlying layer easily.

(ii) Method for Forming the Underlying Layer

In the embodiment, the underlying layer can be formed by coating the underlying layer forming coating-solution.

The method for coating the underlying layer forming coating-solution is not particularly limited. Examples include die coating, spin coating, dip coating, roll coating, bead coating, spray coating, bar coating, gravure coating, inkjet printing, screen printing, and offset printing. Among these, spin coating or die coating is preferably used. These methods make it possible to precisely form the underlying layer to have a given film thickness.

After the underlying layer forming coating-solution is coated, drying treatment is usually conducted. The method for the drying may be an ordinary drying method, and is, for example, a heating method. Specifically, the following can be used: a method of allowing the coated coating-solution to pass through or stand still in a device for heating the whole of a specific space, such as an oven; a method of blowing a hot wind onto the coating-solution; a method of heating the coating-solution directly by far-infrared rays or the like; or a method of heating the coating-solution with a hot plate. The heating temperature at this time is not particularly limited if the temperature is a temperature which causes the above-mentioned polymer material not to be denatured, degenerated or the like. The temperature ranges usually from about 30 to 300° C., preferably in a range of 40 to 150° C., and more preferably in a range of 50 to 110° C. The heating time is appropriately adjusted.

The thickness of the resultant underlying layer is not particularly limited, and is appropriately adjusted in accordance with the usage of the laminated body manufactured by the invention. Specifically, the thickness maybe in a range of 0.2 to 500 nm, and is preferably in a range of 1 to 300 nm for the following reason: when the laminated body manufacturing method of the invention is applied to a manufacturing method of an organic device such as an organic electroluminescent element or an organic thin-film solar cell, the thickness of the underlying layer is preferably within the above-mentioned range.

(2) Upper Layer Forming Step

The upper layer forming step in the embodiment is a step of coating an upper layer forming coating-solution on the underlying layer, thereby forming an upper layer. The upper layer forming coating-solution and a method for forming the upper layer will be described below.

(i) Upper Layer Forming Coating-Solution

The upper layer forming coating-solution used in the embodiment is usually a coating-solution comprising a constituent material of the upper layer, and is prepared by dissolving or dispersing the constituent material into a solvent. The constituent material of the upper layer and the solvent will be described below.

(Constituent Material of the Upper Layer)

The constituent material of the upper layer, which is used in the embodiment, is not particularly limited if the material is a material which can be dissolved or dispersed in the upper layer forming coating-solution, which will be detailed later, and is appropriately selected in accordance with the kind of the solvent used in the upper layer forming coating-solution and the usage of the laminated body manufactured by the invention. Specifically, materials having various functions can be used. In the embodiment, organic semiconductor materials are preferably used since they have advantages described in the above-mentioned column of the underlying layer forming step.

Examples of the organic semiconductor materials include a p type organic semiconductor material, an n type organic semiconductor material, an organic semiconductor material which forms an charge transfer complex composed of an electron-donating compound and an electron-accepting compound, and an organic semiconductor material doped with an electron-donating compound or an electron-accepting compound. In the embodiment, any one of the organic semiconductor material of a low molecular type and that of a high molecular type can be used. Among these, the high molecular organic semiconductor material is preferably used for the following reason: the high molecular organic semiconductor material is generally formed into a film by coating since the material is not easily formed into a film by a vacuum film-forming method such as vapor deposition or sputtering; thus, the advantageous effects of the invention can be remarkably exhibited.

The low molecular p type organic semiconductor material is not particularly limited if the material has a function as an electron donor. Examples thereof include a naphthalene, an anthracene, a tetracene, a pentacene, a hexacene, a porphyrin, a phthalocyanine, a melocyanine, a chlorophyll, a triphenylamine, a triarylamine, a carbazole, and derivatives thereof.

The low molecular n type organic semiconductor material is not particularly limited If the material has a function as an electron acceptor. Examples thereof include a perylene, a quinine, a quinacridon, derivatives thereof, an aluminum quinolinol complex (Alq3), a basocuproin (BCP) or a basophenanthroline (Bphen).

Specific examples of the high molecular p type organic semiconductor material and the high molecular n type organic semiconductor material are the same as described in the above-mentioned column of the underlying layer forming step. The high molecular p and n type organic semiconductor materials each used in the constituent material of the upper layer do not need to have such a given weight-average molecular weight as the above-mentioned polymer material has.

An example of the low molecular organic semiconductor material which forms a charge transfer complex made of an electron-donating compound and an electron-accepting compound is a material which forms a charge transfer complex made of an electron-donating compound, such as a tetrathiofulvalene or a tetramethylphenylenediamine, and an electron-accepting compound, such as a tetracyanoquinodimethane or a tetracyanoethylene.

An example of the organic semiconductor material doped with an electron-donating compound or an electron-accepting compound is a material wherein the above-mentioned p type or the n type organic semiconductor material is doped with an electron-donating compound or an electron-accepting compound.

The electron-donating compound and the electron-accepting compound for the doping are the same as described in the above-mentioned column of the underlying layer forming step.

In the embodiment, electroconductive polymer materials out of the above-mentioned organic semiconductor materials are preferably used since the materials have such advantageous effects as described in the column of the underlying layer forming step.

Specific examples of the electroconductive polymer materials are the same as described in the column of the underlying layer forming step.

(Solvent)

The solvent used in the upper layer forming coating-solution is not particularly limited if the solvent is a solvent in which the above-mentioned constituent material of the upper layer can be dissolved or dispersed. In the embodiment, the above-mentioned polymer material has a large weight-average molecular weight, as described above; thus, the polymer material would be not easily dissolved in any ordinary solvent. For this reason, the solvent used in the upper layer forming coating-solution is not limited.

The solvent used in the upper layer forming coating-solution may or may not have compatibility with the solvent used in the underlying layer forming coating-solution. When the solvent used in the upper layer forming coating-solution does not have compatibility with the solvent in the underlying layer forming coating-solution, the polymer material contained in the underlying layer hardly has affinity with the solvent in the upper layer forming coating-solution. As a result, this case has an advantage that the polymer material does not elute out and the like. On the other hand, when the solvent in the upper layer forming coating-solution has compatibility with the solvent in the underlying layer forming coating-solution, the polymer material contained in the underlying layer has affinity with the solvent in the upper layer forming coating-solution. However, the weight-average molecular weight of the polymer material is large, as described above; thus, the polymer material is restrained from eluting into the solvent in the upper layer forming coating-solution.

Consequently, when the solvent in the upper layer forming coating-solution has compatibility with the solvent in the underlying layer forming coating-solution, the advantageous effects of the invention are remarkably exhibited.

Specific examples of the solvent used in the upper layer forming coating-solution are the same solvents as can be used in the underlying layer forming coating-solution.

(ii) Method for Forming the Upper Layer

In the embodiment, the upper layer can be formed by coating the upper layer forming coating-solution on the underlying layer.

The method for coating the upper layer forming coating-solution is not particularly limited, and examples thereof include die coating, spin coating, dip coating, roll coating, bead coating, spray coating, bar coating, gravure coating, inkjet printing, screen printing, and offset printing. Among these, spin coating or die coating is preferably used. These methods make it possible to precisely form the upper layer to have a given film thickness.

After the upper layer forming coating-solution is coated, the coated coating-solution is usually subjected to drying treatment. The method for the drying may be the same as described in the column of the underlying layer forming step.

The thickness of the resultant upper layer is not particularly limited, and is appropriately adjusted in accordance with the laminated body manufactured by the invention. Specifically, the thickness is equivalent with that of the underlying layer.

(3) Others

In the embodiment, two or more layers can be laminated by repeating the underlying layer forming step and the upper layer forming step. In the case of laminating, for example, three layers, the first layer is formed through the underlying layer forming step, next the second layer is formed through the underlying layer forming step also, and lastly the third layer is formed through the upper layer forming step. When the first and second layers are each formed by use of a polymer material having the given weight-average molecular weight, the three layers can be formed stably. In this way, plural layers can be laminated in the invention.

The laminated body manufacturing method of the embodiment can be applied to a manufacturing method of an organic device such as an organic thin-film solar cell, an organic electroluminescent element, an organic semiconductor element, a light emitting diode, or an optical sensor. The method of the embodiment is preferable as a manufacturing method of an organic thin-film solar cell.

2. Second Embodiment

The second embodiment of the laminated body manufacturing method of the invention comprises an underlying layer forming step of coating an underlying layer forming coating-solution comprising an insulating resin material to form an underlying layer, and an upper layer forming step of coating an upper layer forming coating-solution on the underlying layer to form an upper layer.

In the embodiment, the underlying layer comprises the insulating resin material, whereby the solvent resistance can be improved and the strength of the underlying layer to be obtained can be further improved.

The upper layer forming step, and other points of the laminated body manufacturing method are the same as those described in the first embodiment. Thus, description thereof is omitted herein. The underlying layer forming step will be described below.

(1) Underlying Layer Forming Step

The underlying layer forming step in the embodiment is a step of coating an underlying layer forming coating-solution comprising an Insulating resin material, thereby forming an underlying layer. The underlying layer forming coating-solution will be described below. The method for forming the underlying layer is the same as those described in the first embodiment. Thus, description thereof is omitted herein.

(1) Underlying Layer Forming Coating-Solution

The underlying layer forming coating-solution used in the embodiment is a coating-solution comprising an insulating resin material, and is usually prepared by dissolving or dispersing this insulating resin material into a solvent. The following will describe the insulating resin material and the solvent.

(Insulating Resin Material)

The insulating resin material used in the embodiment is not particularly limited if the material is a material for improving the solvent resistance of the underlying layer and making the film strength thereof higher. Examples thereof include a thermoplastic resin material, a thermosetting resin material, and an ionizing radiation cure resin material.

Specific examples of the thermoplastic resin material include a polypropylene, a polyethylene, a polystyrene, a polyvinyl acetate, a polyamide, a polyvinyl chloride, a polyurethane, a polyethylene terephthalate, a polyvinylidene chloride, and a polyacrylonitrile.

Specific examples of the thermosetting resin material include a phenol resin, a melamine resin, an urea resin, an urethane resin, and an epoxy resin.

The ionizing radiation cure resin material may be an ultraviolet curable resin material or an electron beam curable resin material. Specific examples of the ultraviolet curable resin material include an urethane acrylate, an epoxy acrylate, an ester acrylate, an acrylate, an epoxy, a vinyl ether, and a oxetane. Specific examples of the electron beam curable resin material include an unsaturated polyester, an unsaturated acryl, a polyepoxy acrylate, an urethane acrylate, a polyester acrylate, a polyether acrylate, a polyene, and a polythiol.

The weight-average molecular weight of the insulating resin material is preferably 10,000 or more, more preferably 50,000 or more. Also, the weight-average molecular weight is preferably 3,000,000 or less, more preferably 1,000,000 or less. If the weight-average molecular weight of the insulating resin material is too small, the insulating resin material may be dissolved into the solvent in the upper layer forming coating-solution. Conversely, if the weight-average molecular weight of the insulating resin material is too large, the viscosity of the underlying layer forming coating-solution is high so that the coating-solution may not be easily turned into an even coated film.

The method for measuring the weight-average molecular weight is the same as those described in the first embodiment.

(Solvent)

The solvent used in the underlying layer forming coating-solution is not particularly limited if the solvent is a solvent wherein the above-mentioned insulating resin material can be dissolved or dispersed. Specific examples thereof are the same solvents as can be used in the underlying layer forming coating-solution in the first embodiment.

(Different Constituent Material of the Underlying Layer)

The underlying layer forming coating-solution used in the embodiment is not particularly limited if the coating-solution is a coating-solution comprising the insulating resin material. In the case of forming the underlying layer which has various functions, it is preferred that the coating-solution comprises a different constituent material besides the insulating resin material. The constituent material, for the underlying layer, which can be used at this time is appropriately selected in accordance with the usage of the laminated body manufactured by the invention. Materials having various functions can be used.

The materials, which have various functions, may be, for example, the organic semiconductor materials as used for the upper layer forming coating-solution described in the first embodiment.

B. Manufacturing Method of an Organic Device

The following will describe the manufacturing method of an organic device.

The organic device manufacturing method of the invention comprises a substrate, a first electrode layer formed on the substrate, an organic semiconductor layer formed on the first electrode layer and comprising at least two organic layers, and a second electrode layer formed on the organic semiconductor layer, wherein the above-mentioned laminated body manufacturing method is used to form the organic semiconductor layer.

In other words, when an organic semiconductor layer comprising at least two organic layers is formed, an underlying layer forming coating-solution comprising a polymer material is coated on a first electrode layer to form an underlying layer (organic layer), and an upper layer forming coating-solution comprising an organic semiconductor material is coated onto this underlying layer to form an upper layer (organic layer).

In the invention, any one of the first and second embodiments of the above-mentioned laminated body manufacturing method can be used. Specifically, a high molecular organic semiconductor material having the given weight-average molecular weight may be used or an insulating resin material may be used as the polymer material. In the case of using an insulating resin material as the polymer material, an underlying layer forming coating-solution comprising the insulating resin material and an organic semiconductor material is used.

According to the invention, the polymer material in the underlying layer can be prevented from eluting into the solvent in the upper layer forming coating-solution, or the like since the above-mentioned laminated body manufacturing method is used. The invention also has an advantage that the kind of the organic semiconductor material and that of the solvent used in the upper layer forming coating-solution are not limited. This makes it possible to use an organic semiconductor material having a desired nature to laminate organic layers each having a target function and improve the performance of an organic device to be obtained. Additionally, an organic semiconductor layer comprising plural organic layers can easily be formed; thus, it is possible to obtain an organic device having an organic semiconductor layer wherein organic layers having various functions are laminated.

The following will describe the method for forming each of the constituent members in the organic device manufacturing method of the invention.

1. Method for Forming the Organic Semiconductor Layer

As the method for forming the organic semiconductor layer -n the invention, the above-mentioned laminated body manufacturing method is used. The following will separately describe a case where the first embodiment of the laminated body manufacturing method is used (first case) and a case where the second embodiment thereof is used (second case).

(1) First Case

The first case of the organic semiconductor layer forming method is a case where at the time of forming an organic semiconductor layer comprising at least two organic layers, an underlying layer forming coating-solution comprising a high molecular organic semiconductor material having the given weight-average molecular weight is coated on a first electrode layer to form an underlying layer (organic layer), and an upper layer forming coating-solution comprising an organic semiconductor material is coated on this underlying layer to form an upper layer (organic layer).

The organic semiconductor material used in each of the organic layers constituting the organic semiconductor layer is appropriately selected in accordance with the function of the organic device to be obtained. A high molecular organic semiconductor material is used in the organic layer as the underlying layer. Any one of a high molecular organic semiconductor material and a low molecular organic semiconductor material can be used in the organic layer as the upper layer. The organic semiconductor materials are same as the organic semiconductor materials described in the above-mentioned column “A. Manufacturing method of a laminated body”.

The thickness of each of the organic layers is not particularly limited, and is appropriately adjusted in accordance with the function of the organic device. Specifically, the thickness is same as the thickness of the underlying layer described in the above-mentioned column “A. Manufacturing method of a laminated body”.

(2) Second Case

The second case of the organic semiconductor layer forming method is a case where at the time of forming an organic semiconductor layer comprising at least two organic layers, an underlying layer forming coating-solution comprising an insulating resin material and an organic semiconductor material is coated on a first electrode layer to form an underlying layer (organic layer) , and an upper layer forming coating-solution comprising an organic semiconductor material is coated on this underlying layer to form an upper layer (organic layer).

The organic semiconductor material used in each of the organic layers constituting the organic semiconductor layer is appropriately selected in accordance with the function of the organic device to be obtained. Any one of a high molecular organic semiconductor material and a low molecular organic semiconductor material can be used in each of the organic layer as the underlying layer and the organic layer as the upper layer. The organic semiconductor materials are same as the organic semiconductor materials described in the above-mentioned column “A. Manufacturing method of a laminated body”.

The thickness of each of the organic layers is not particularly limited, and is appropriately adjusted in accordance with the function of the organic device. Specifically, the thickness is same as the thickness of the underlying layer described in the above-mentioned column “A. Manufacturing method of a laminated body”.

2. Method for Forming the First and Second Electrode Layers

The material used in the first electrode layer and the second electrode layer in the present invention is not particularly limited as long as the material has electroconductivity, and is appropriately selected under consideration of, for example, the radiating direction of light or the taking-out direction thereof, the work function which the material should have, and others.

For example, in the case of radiating light onto the side of the substrate or taking out light therefrom, the first electrode layer is preferably rendered a transparent electrode. The transparent electrode may be an ordinarily used transparent electrode. Specific examples thereof include In—Zn—O (IZO), In—Sn—O (ITO), ZnO—Al, and Zn—Sn—O.

Moreover, for example, in the case of using a material having a low work function for the second electrode layer, it is preferred to use a material having a high work function for the first electrode layer. Examples of the high work function material include Au, Ag, Co, Ni, Pt, C, ITO, SnO₂, SnO₂ doped with fluorine, and ZnO. Examples of the low work function material include Li, In, Al, Ca, Mg, Sm, Tb, Yb, Zr, and LiF.

The method for forming the first electrode layer and the second electrode layer may be an ordinary electrode-forming method. Examples thereof include PVD methods such as vacuum vapor deposition, sputtering and ion plating; and CVD methods.

The first electrode layer and the second electrode layer may each be formed onto the whole surface, or formed into a pattern form. The method for the patterning is not particularly limited as long as the method is a method capable of forming a desired pattern with a high precision. The method is, for example, a photolithography.

The first electrode layer and the second electrode layer may each be a single layer or a multi-layer wherein materials having different work functions are used. The Thickness of the first electrode layer and the second electrode layer are each appropriately adjusted in accordance with the function of the organic device.

3. Substrate

The substrate used in the present invention may be transparent or opaque. For example, in the case of radiating or taking light from the side of the substrate, it is preferred to use a transparent substrate. This transparent substrate is not particularly limited, and may be a plate made of a nonflexible transparent rigid material such as quartz glass, Pyrex (registered trademark) glass or synthetic quartz, or a film or plate made of a transparent flexible material such as transparent resin or resin for optics.

Of the above, the flexible material made of transparent resin or the like is preferred as the substrate. This is because the transparent resin film is so excellent in workability that the film is useful for decreasing the production costs, making the substrate light,and realizing an organic device which is not easily cracked and further the applicability of the film to various articles, such as the application thereof to an article having a curved surface, becomes higher.

4. Usage

The organic device manufacturing method of the invention can be applied to, for example, a manufacturing method of an organic thin-film solar cell, an organic electroluminescent element, or the like. The method of the invention is particularly useful as the manufacturing method of an organic thin-film solar cell.

C. Manufacturing Method of an Organic Thin-Film Solar Cell

The following will describe the organic thin-film solar cell manufacturing method of the invention.

The method is a method wherein the above-mentioned organic device manufacturing method is used.

The organic device manufacturing method is a method of using the above-mentioned laminated body manufacturing method to form an organic semiconductor layer comprising at least two organic layers. In the invention, the organic semiconductor layer has two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.

In other words, at the time of forming at least two organic layers selected from the group consisting of electron hole transporting layers, hole transporting layers and electron transporting layers, it is preferred to coat an underlying layer forming coating-solution comprising a polymer material on a first electrode layer to form an underlying layer, and then coat an upper layer forming coating-solution comprising a p type organic semiconductor material or an n type organic semiconductor material on this underlying layer to form an upper layer.

At this time, in accordance with the selected embodiment of the above-mentioned laminated body manufacturing method, a high molecular organic semiconductor material having the given weight-average molecular weight maybe used or an insulating resin material may be used as the polymer material. In the case of using an insulating resin material as the polymer material, there is used an underlying layer forming coating-solution comprising the insulating resin material and a p type or the n type organic semiconductor material.

Organic thin-film solar cells manufactured by the invention will be described below with reference to the attached drawings.

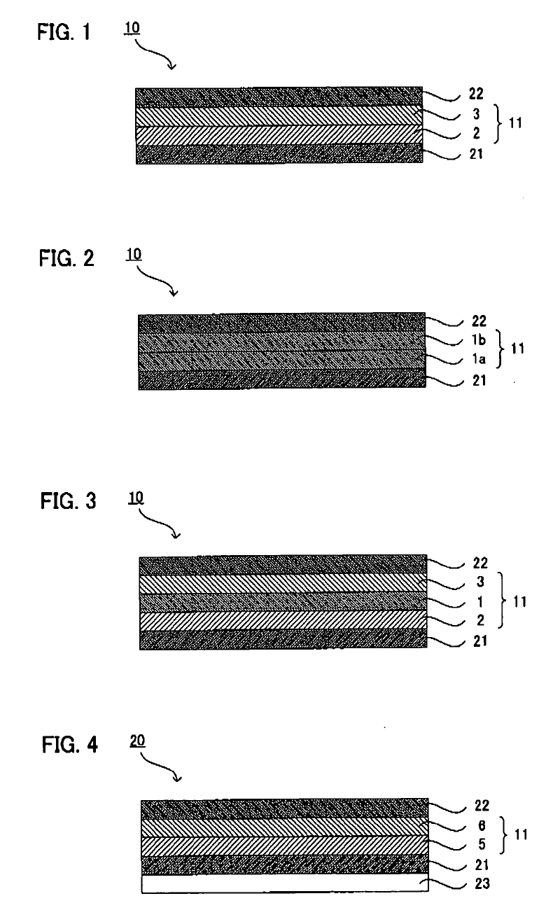

FIG. 1 is a schematic sectional view illustrating an example of the organic thin-film solar cell manufactured by the invention. In an organic thin-film solar cell 10 illustrated in FIG. 1, a first electrode layer 21 and a second electrode layer 22 are formed on both surfaces of an organic semiconductor layer 11, respectively. The organic semiconductor layer 11 has a hole transporting layer 2 and an electron transporting layer 3. Since pn junction is formed in the interface between the hole transporting layer 2 and the electron transporting layer 3 to generate charge separation, the hole transporting layer 2 and the electron transporting layer 3 exhibit photoelectric conversion function in the form of a pair of the two layers.

The “photoelectric conversion function” referred to herein is a function of contributing to charge separation in an organic thin-film solar cell to transport the resultant electrons and holes in opposite directions toward the first electrode layer and the second electrode layer, respectively.

In the invention, the above-mentioned laminated body manufacturing method is used; therefore, in the case of the organic thin-film solar cell 10 illustrated in FIG. 1, at the time of forming the electron transporting layer on the hole transporting layer, it is possible to prevent any p type organic semiconductor material from eluting from the hole transporting layer (underlying layer) into a solvent of coating-solution for forming the electron transporting layer (upper layer forming coating-solution). There is produced an advantage that the kinds of the n type organic semiconductor material and the solvent used in coating-solution for forming the electron transporting layer are not limited.

In the invention, therefore, at the time of forming one or more hole transporting layers, one or more electron transporting layers and one or more electron hole transporting layers, one or more p type organic semiconductor materials and one or more n type organic semiconductor materials which each have a desired nature can be used. Additionally, an organic semiconductor layer having plural organic layers selected from the group consisting of the hole transporting layer(s), the electron transporting layer(s) and the electron hole transporting layer(s) can easily be formed. For this reason, an organic thin-film solar cell having a high performance can be manufactured through a simple process.

Another example of the organic thin-film solar cell manufactured by the invention is illustrated in FIG. 2. In an organic thin-film solar cell 10 illustrated in FIG. 2, a first electrode layer 21 and a second electrode layer 22 are formed on both surfaces of an organic semiconductor layer 11, respectively. The organic semiconductor layer 11 has two electron hole transporting layers la and lb. Since the electron hole transporting layers each contain a p type organic semiconductor material and an n type organic semiconductor material, pn junction is formed in each of the layers to generate charge separation. The resultant electrons and holes are then shifted in opposite directions toward the first electrode layer 21 and the second electrode layer 22, respectively.

In such an organic semiconductor layer, wherein plural electron hole transporting layers having photoelectric conversion function are laminated, for example, organic semiconductor materials having absorption wavelength ranges different from each other can be used in the electron hole transporting layers, respectively; accordingly, the absorption wavelength range of the whole of the organic semiconductor layer can be made broader. In the case of using, for example, an organic semiconductor material having the same absorption wavelength range in each of the electron hole transporting layers, the thickness of the organic semiconductor layer which has the plural electron hole transporting layers becomes larger than that of any organic semiconductor layer having a single electron hole transporting layer; therefore, with the increase in the thickness, the absorbance would be able to be made larger. Furthermore, the lamination of the plural electron hole transporting layers makes it possible to expect an improvement in the electromotive force, as in the case when plural organic thin-film solar cells are connected in series. Accordingly, the lamination of a plurality of the electron hole transporting layers makes it possible to generate electric power on a broad wavelength range and manufacture an organic thin-film solar cell capable of realizing a high photoelectric conversion efficiency.

A further example of the organic thin-film solar cell manufactured by the invention is illustrated in FIG. 3. In an organic thin-film solar cell 10 illustrated in FIG. 3, electrode layers 21 and 22 are formed on both surfaces of an organic semiconductor layer 11, respectively. In this organic semiconductor layer 11, a hole transporting layer 2, an electron hole transporting layer 1, and an electron transporting layer 3 are laminated in this order. In the organic semiconductor layer 11, the electron hole transporting layer 1 exhibits photoelectric conversion function so that electrons and holes are generated in the electron hole transporting layer 1. The generated electrodes and holes are shifted in opposite directions toward the first electrode layer 21 and the second electrode layer 22, respectively. At this time, since the hole transporting layer 2 and the electron transporting layer 3 are arranged on the interface between the electron hole transporting layer 1 and the first and second electrode layers 31 and 32, respectively, resistance barriers in interfaces between the electron hole transporting layer 1 and the first and second electrode layers 31 and 32 can be decreased, and thus holes and electrons can be taken out easily.

In the invention, therefore, an electron hole transporting layer, a hole transporting layer and an electron transporting layer may be combined with each other and laminated into plural layers, thereby making It possible to use light effectively and manufacture an organic thin-film solar cell capable of gaining a high charge taking-out efficiency. The electron hole transporting layer, the hole transporting layer and the electron transporting layer can be laminated without forming any interposing layer. Thus, there is produced an advantage that the manufacturing process can be made simple.

In the invention, when an organic semiconductor layer is formed with two organic layers selected from the group consisting of electron hole transporting layers, hole transporting layers and electron transporting layers, the layers are laminated to have, for example, the following structure: (1) hole transporting layer/electron transporting layer; (2) electron hole transporting layer/electron hole transporting layer; (3) hole transporting layer/electron hole transporting layer; (4) electron hole transporting layer/electron transporting layer; or the like.

In this case, the manufacturing process is appropriately selected in accordance with the layer which should be rendered as an underlying layer, and the selected embodiment of the above-mentioned laminated body manufacturing method.

For example, in the case of using the first embodiment of the laminated body manufacturing method and forming an electron transporting layer on a hole transporting layer, a coating-solution for forming the hole transporting layer (underlying layer forming coating-solution) comprising a high molecular p type organic semiconductor material having the given weight-average molecular weight is coated to form the hole transporting layer; and then a coating-solution for forming the electron transporting layer (upper layer forming coating-solution) comprising an n type organic semiconductor material is coated onto this hole transporting layer to form the electron transporting layer.

For example, in the case of using the second embodiment of the laminated body manufacturing method and forming an electron transporting layer on a hole transporting layer, a coating-solution for forming the hole transporting layer (underlying layer forming coating-solution) comprising an insulating resin material and a p type organic semiconductor material is coated to form the hole transporting layer; and then a coating-solution for forming the electron transporting layer (upper layer forming coating-solution) comprising an n type organic semiconductor material is coated onto this hole transporting layer to form the electron transporting layer.

In the invention, when an organic semiconductor layer is formed with three organic layers selected from the group consisting of electron hole transporting layers, hole transporting layers and electron transporting layers, the layers are laminated to nave, for example, the following structure: (1) hole transporting layer/hole transporting layer/electron transporting layer; (2) hole transporting layer/electron transporting layer/electron transporting layer; (3) electron hole transporting layer/electron hole transporting layer/electron hole transporting layer; (4) hole transporting layer/electron hole transporting layer/electron hole transporting layer; (5) electron hole transporting layer/electron hole transporting layer/electron transporting layer; (6) electron hole transporting layer/hole transporting layer/electron hole transporting layer; (7) electron hole transporting layer/electron transporting layer/electron hole transporting layer; (8) hole transporting layer/electron hole transporting layer/electron transporting layer; or the like.

In this case also, the manufacturing process is appropriately selected in accordance with the layers which should be rendered as underlying layers, and the selected embodiment of the above-mentioned laminated body manufacturing method.

For example, in the case of using the first embodiment of the laminated body manufacturing method and forming an electron hole transporting layer on a hole transporting layer and then forming an electron transporting layer on this electron hole transporting layer, there is carried out a process of coating a coating-solution for forming the hole transporting layer (underlying layer forming coating-solution) comprising a high molecular p type organic semiconductor material having the given weight-average molecular weight to form the hole transporting layer; next coating, on this hole transporting layer, a coating-solution for forming the electron hole transporting layer (underlying layer forming coating-solution) comprising a high molecular p type organic semiconductor material having the given weight-average molecular weight and a high molecular n type organic semiconductor material to form the electron hole transporting layer; and lastly coating, on the electron hole transporting layer, a coating-solution for forming the electron transporting layer (upper layer forming coating-solution) comprising an n type organic semiconductor material to form the electron transporting layer.

For example, in the case of using the second embodiment of the laminated body manufacturing method and forming an electron hole transporting layer on a hole transporting layer and then forming an electron transporting layer on this electron hole transporting layer, there is carried out a process of coating a coating-solution for forming the hole transporting layer (underlying layer forming coating-solution) comprising an insulating resin material and a p type organic semiconductor material to form the hole transporting layer; next coating, on this hole transporting layer, a coating-solution for forming the electron hole transporting layer (underlying layer forming coating-solution) comprising an insulating resin material, a p type organic semiconductor material and an n type organic semiconductor material to form the electron hole transporting layer; and lastly coating, on the electron hole transporting layer, a coating-solution for forming the electron transporting layer (upper layer forming coating-solution) comprising an n type organic semiconductor material to form the electron transporting layer.

Of course, it is possible in the invention to form an organic semiconductor layer having 4or 5, or more organic layers selected from the group consisting of electron hole transporting layers, hole transporting layers, and electron transporting layers, specific examples of the layer structure thereof being omitted herein.

The method for forming the first and second electrode layers, and the substrate, which can be used, are the same as described in the above-mentioned column “B. Manufacturing method of an organic device”. Thus, description thereof is omitted herein.

D. Organic device

The following will describe the organic device of the invention.

The organic device of the invention comprises a substrate, a first electrode layer formed on the substrate, an organic semiconductor layer formed on the first electrode layer and comprising a first organic layer comprising a high molecular organic semiconductor material having a weight-average molecular weight of 100,000 or more and a second organic layer formed on the first organic layer, and a second electrode layer formed on the organic semiconductor layer.

FIG. 4 is a schematic sectional view illustrating an example of the organic device of the invention. As illustrated in FIG. 4, an organic device 20 of the example is a device wherein a first electrode layer 21, an organic semiconductor layer 11 and a second electrode layer 22 are laminated in this order on a substrate 23. The organic semiconductor layer 11 has a first organic layer 5 and a second organic layer 6.

When the organic semiconductor layer is formed in the invention, the second organic layer is formed on the first organic layer. The first organic layer contains a high molecular organic semiconductor material having the given weight-average molecular weight; therefore, at the time of forming the second organic layer, the high molecular organic semiconductor material in the first organic layer can be prevented from eluting into a solvent in a coating-solution for forming the second organic layer. Additionally, the organic semiconductor material used in the second organic layer and the used solvent are not limited; therefore, an organic semiconductor material having a desired nature can be used. Accordingly, the present device can be rendered as an organic device having a high performance.

Each of the constituents of the organic device of the invention will be described below.

1. Organic Semiconductor Layer

The organic semiconductor layer used in the invention is a layer having a first organic layer and a second organic layer. About the first and second organic layers, their functions are appropriately selected in accordance with the purpose of the organic device of the invention. Specifically, the first or second organic layer is a layer such as an electron hole transporting layer, a hole transporting layer, or an electron transporting layer in an organic thin-film solar cell, or an light emitting layer, a hole injecting layer or an electron injecting layer in an organic electroluminescent element.

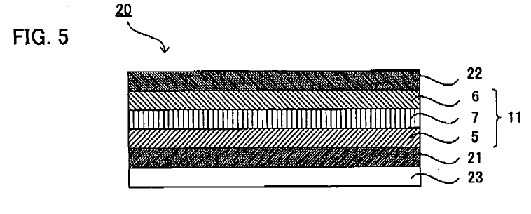

It is sufficient that the organic semiconductor layer used in the invention is a layer having at least the first and second organic layers. As illustrated in, for instance, FIG. 5, the organic semiconductor layer may have a third organic layer 7 between a first organic layer 5 and a second organic layer 6. The organic semiconductor layer may have a fourth organic layer formed between a third organic layer and a second organic layer, the structure of which is not illustrated. In other words, the organic semiconductor layer is a layer having two or more organic layers, and a further organic layer may be formed between the first and second organic layers thereof.

The “first organic layer” referred to herein is a layer which comprises a high molecular organic semiconductor material having the given weight-average molecular weight and is formed nearest to the first electrode layer among the layers constituting the organic semiconductor layer. The “second organic layer” is a layer formed nearest to the second electrode layer among the same layers.

When the organic semiconductor layer has, for example, three organic layers, at the time of forming the organic semiconductor layer the first, third and second organic layers are laminated in this order. Thus, the first organic layer becomes an underlying layer of the third organic layer, the third organic layer becomes an underlying layer of the second organic layer. Consequently, the first and third organic layers are each a layer comprising a high molecular organic semiconductor material having the given weight-average molecular weight.

The first organic layer used in the invention is a layer comprising a high molecular organic semiconductor material having a weight-average molecular weight of 100,000 or more.

The weight-average molecular weight of the organic semiconductor material is same as that of the polymer material described in the above-mentioned column “1. First embodiment” in “A. Manufacturing method of a laminated body”. The organic semiconductor material used in the first layer is same as that used in the underlying layer described in the column “A. Manufacturing method of a laminated body”. Thus, description thereof is omitted herein.

The second organic layer used in the invention is a layer which comprises an organic semiconductor material and may comprise the organic semiconductor material of a low molecular type or a high molecular type.

The organic semiconductor material used in the second organic layer is same as that used in the upper layer described in the above-mentioned column “A. Manufacturing method of a laminated body”. Thus, description thereof is omitted herein.

In the case of forming, between the first and second organic layers, different organic layers such as third and fourth organic layers, these organic layers are layers which each comprises a high molecular organic semiconductor material having the given weight-average molecular weight in the same manner as the first organic layer.

2. Others

The organic device of the invention can be applied to, for example, an organic thin-film solar cell, an organic electroluminescent element, or the like. In particular, the organic device is useful as an organic thin-film solar cell.

The organic device of the invention can be manufactured by the above-mentioned organic device manufacturing method. In other words, the organic device can be manufactured by the above-mentioned laminated body manufacturing method.

The first electrode layer, the second electrode layer and the substrate are the sane as described in the above-mentioned column “B. Manufacturing method of an organic device”.

E. Organic Thin-Film Solar Cell

The organic thin-film solar cell of the invention will be described below.

The organic thin-film solar cell of the invention is an organic thin-film solar cell wherein the above-mentioned organic device is used, and the organic semiconductor layer of the organic device has two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.

Since the organic thin-film solar cell of the invention is a cell wherein the above-mentioned organic device is used, a high photoelectric conversion efficiency can be obtained.

Each of the constituents of the organic thin-film solar cell of the invention will be described below.

1. Organic Semiconductor Layer

The organic semiconductor layer used in the invention is a layer having two or more organic layers selected from the group consisting of electron hole transporting layers, hole transporting layers and electron transporting layers.

The electron hole transporting layers, the hole transporting layers and the electron transporting layers are the same as described in the above-mentioned column “C. Manufacturing method of an organic thin-film solar cell”.

When the organic semiconductor layer has, for example, two organic layers, examples of the structure of the organic semiconductor layer include (1) hole transporting layer/electron transporting layer; (2) electron hole transporting layer/electron hole transporting layer; (3) hole transporting layer/electron hole transporting layer; and (4) electron hole transporting layer/electron transporting layer.

In this case, any of the two organic layers may be rendered as a layer comprising a high molecular organic semiconductor material having the given weight-average molecular weight. In the case of forming, for example, an electron transporting layer on a hole transporting layer, the hole transporting layer is rendered as a layer comprising a high molecular organic semiconductor material having the given weight-average molecular weight since the hole transporting layer becomes an underlying layer of the electron transporting layer.

When the organic semiconductor layer has, for example, three organic layers, examples of the structure of the organic semiconductor layer include (1) hole transporting layer/hole transporting layer/electron transporting layer; (2) hole transporting layer/electron transporting layer/electron transporting layer; (3) electron hole transporting layer/electron hole transporting layer/electron hole transporting layer; (4) hole transporting layer/electron hole transporting layer/electron hole transporting layer; (5) electron hole transporting layer/electron hole transporting layer/electron transporting layer; (6) electron hole transporting layer/hole transporting layer/electron hole transporting layer; (7) electron hole transporting layer/electron transporting layer/electron hole transporting layer; and (8) hole transporting layer/electron hole transporting layer/electron transporting layer.

In the case, any layer out of the layers constituting the outermost surfaces of the organic semiconductor layer may be rendered as a layer comprising a high molecular organic semiconductor material having the given weight-average molecular weight. For example, in the case of forming an electron hole transporting layer on a hole transporting layer and then forming an electron transporting layer on the electron hole transporting layer, the hole transporting layer and the electron hole transporting layer are each rendered as a layer comprising a high molecular organic semiconductor material having the given weight-average molecular weight since the hole transporting layer becomes an underlying layer of the electron hole transporting layer and the electron hole transporting layer becomes an underlying layer of the electron transporting layer.

When a hole transporting layer becomes an underlying layer as described above, this layer comprises a high molecular p type organic semiconductor material having the given weight-average molecular weight. However, when a hole transporting layer does not become any underlying layer, this layer may comprise a low molecular p type organic semiconductor material or may comprise a high molecular p type organic semiconductor material.

Similarly, when an electron transporting layer becomes an underlying layer, this layer comprises a high molecular n type organic semiconductor material having the given weight-average molecular weight. When an electron transporting layer does not become any underlying layer, this layer may comprise a low molecular n type organic semiconductor material or may comprise a high molecular n type organic semiconductor material.

On the other hand, any electron hole transporting layer comprises a p type organic semiconductor material and an n type organic semiconductor material; therefore, when an electron hole transporting layer becomes an underlying layer, it is sufficient that at least one of the p type and n type organic semiconductor materials has the given weight-average molecular weight. When an electron hole transporting layer does not become any underlying layer, this layer may comprise any one of a low molecular p type organic semiconductor material and a high molecular p type organic semiconductor material, and may comprise any one of a low molecular n type organic semiconductor material and a high molecular n type organic semiconductor material.

The p type and n type organic semiconductor materials are the same as described in the above-mentioned column “A. Manufacturing method of a laminated body”. Thus, description thereof is omitted herein.

In order to generate charges effectively in an electron hole transporting layer, it is preferred that a p type organic semiconductor material and an n type organic semiconductor material are evenly dispersed in the electron hole transporting layer. At this time, the blend ratio between the p and n type organic semiconductor materials is appropriately adjusted into an optimal blend ratio in accordance with the kinds of the used organic semiconductor materials.

The organic semiconductor layer used in the invention may have a vertically laminated structure, or a horizontally laminated structure.

2. Other Constituents

In the invention, a hole taking-out layer or an electron taking-out layer may be formed between the organic semiconductor layer and the first or second electrode layer. The hole taking-out layer is a layer formed to easily take out holes from the organic semiconductor layer to the anode (the first electrode layer or second electrode layer). The electron taking-out layer is a layer formed to easily take out electrons from the organic semiconductor layer to the cathode (the first electrode layer or second electrode layer). In such a way, the charge taking-out efficiency from the organic semiconductor layer to the first or second electrode layer is made high so that the photoelectric conversion efficiency can be improved.

The material used in the hole taking-out layer is not particularly limited if the material is a material for stabilizing the taking-out of holes from the organic semiconductor layer to the anode (the first or second electrode layer). Specific examples thereof include electroconductive organic compounds such as a polyaniline, a polyphenylenevinylene, a polythiophene, a polypyrrole, a polyparaphenylene, a polyacetylene, a polyethylenedioxythiophene (PEDOT), and a triphenyldiamine (TPD) which are each doped; or organic materials which are each capable of forming a charge transfer complex made of an electron-donating compound such as a tetrathiofluvalene or a tetramethylphenylenediamine and an electron-accepting compound such as a tetracyanoquinodimethane or a tetracyancethylene.

The material used in the electron taking-out layer is not particularly limited if the material is a material for stabilizing the taking-out of electrons from the organic semiconductor layer to the cathode (the first or second electrode layer). Specific examples thereof include electroconductive organic compounds such as a polyaniline, a polyphenylenevinylene, a polythiophene, a polypyrrole, a polyparaphenylene, a polyacetylene, a polyethylenedioxythiophene (PEDOT), and a triphenyldiamine (TPD) which are each doped; or organic materials which are each capable of forming a charge transfer complex made of an electron-donating compound such as a tetrathiofluvalene or a tetramethylphenylenediamine and an electron-accepting compound such as a tetracyanoquinodimethane or a tetracyanoethylene. Other examples thereof include alkali metals or alkaline earth metals which are each doped to form a metal doped layer. Preferred examples thereof include metal doped layer of metals such as a basocuproin (BCP) or a basophenanthroline (Bphen) and Li, Cs, Ba or Sr.

If necessary, the organic thin-film solar cell of the invention has the following constituent(s) besides the above-mentioned constituents; for example, a protecting sheet, a filler layer, a barrier layer, a protecting hard coat layer, a strength supporting layer, a dirt-preventing layer, a highly light-reflecting layer, a light-confining layer, an ultraviolet ray/infrared ray blocking layer, a sealing material layer and other functional layers; and an adhesive layer, which is formed between each functional layers in accordance with the layer structure of the organic thin-film solar cell.

The protecting sheet may be formed on the second electrode layer in the invention. The protecting sheet is a layer formed to protect the organic thin-film solar cell from the outside.

The material used in the protecting sheet may be a metal plate or metal foil made of aluminum or the like, or a sheet made of fluorine-contained resin, cyclic polyolefin-contained resin, polycarbonate-contained resin, poly(meth)acrylic-contained resin, polyamide-contained resin, polyester-contained resin, or a composite sheet wherein a weather resistant film and a barrier film are laminated onto each other. The protecting sheet may have barrier property. The protecting sheet may be subjected to coloration or the like so as to have design property. At this time, the protecting sheet may be colored by kneading a pigment into the sheet or by laminating a colored layer, such as a blue hard coat layer, onto the sheet.

The thickness of the protecting sheet is preferably in a range of 20 to 500 μm, more preferably 50 to 200 μm.

The filler layer may be formed between the second electrode layer and the protecting sheet in the invention. The filler layer is a layer formed to cause the rear surface side of the organic thin-film solar cell, that is, the second electrode layer to adhere onto the protecting sheet so as to seal up the organic thin-film solar cell.

The filler layer may be any filler layer that is ordinarily used as the filler layer of solar cells, and may be made of, for example, ethylene-vinyl acetate copolymer resin.

The thickness of the filler layer is preferably in a range of 50 to 2000 μm, more preferably 200 to 800 μm. If the thickness is smaller than this range, the strength falls. Conversely, if the thickness is larger than the range, cracks or the like are easily generated.

The barrier layer may be formed on the surface of the substrate or the surface of the protecting sheet in the invention. When the substrate or the protecting sheet is made of plural layers, the barrier layer may be formed between any two of the layers. The barrier layer is a transparent layer formed to prevent oxygen or water vapor from the outside from entering the organic thin-film solar cell so as to protect the cell of the present invention.

About the barrier layer, the oxygen transmittance thereof is preferably 5 cc/m²/day or less, more preferably 0.1 cc/m²/day or less. The lower limit of the oxygen transmittance is 5.0×10⁻³ cc/m²/day/atm from the viewpoint of the precision of the measuring device which is an oxygen gas transmittance measuring device (OX-TRAN 2/21, manufactured by MOCON Inc,). The oxygen transmittance is a value measured with this device at 23° C. and 90% RH.

The water vapor transmittance is preferably 5 g/m²/day or less, more preferably 0.01 g/m²/day or less at 37.8° C. and 100% RH, and is preferably 1 g/m²/day or less at 40° C. and 90% RH. The lower limit of the water vapor transmittance is 5.0×10⁻³ g/m²/day from the viewpoint of the precision of the measuring device which is a water vapor transmittance measuring device (PERMATRAN-W 3/33, manufactured by MOCON Inc.). The water vapor transmittance is a value measured with this device.

The material for forming the barrier layer is not particularly limited as long as the material is a material capable of gaining the above-mentioned barrier property, and may be, for example, an inorganic oxide, a metal, or a sol gel material. Specifically, examples of the inorganic oxide include a silicon oxide (SiOₓ), an aluminum oxide (AlₙOₘ), a titanium oxide (TiO₂), an yttrium oxide, a boron oxide (B₂O₃), a calcium oxide (CaO), and a silicon oxynitrocarbide (SiOₓN_{y}C_{z}). Examples of the metal include Ti, Al, Mg and Zr. Examples of the sol gel material include siloxane-based so gel materials. These materials may be used alone or in combination of two or more thereof.

The film thickness of the barrier layer is appropriately selected in accordance with the kind of the used material, and others. The film thickness is preferably in a range of 10 to 1000 nm. If the film thickness is smaller than this range, a sufficient barrier property may not be obtained. If the film thickness is larger than the range, a long time is required for the formation of the film.

The barrier layer may be mono-layered or multi-layered. In the case of the multi-layered barrier layer, layers may be directly laminated onto each other or may be stuck onto each other.

Examples of the method for forming the barrier layer include vapor deposition methods such as a sputtering, an ion plating and other PVD methods, and CVD methods; a roll coating; and a spin coating. These methods maybe combined.

The barrier layer is not particularly limited as long as the layer is a layer having the above-mentioned barrier property. Preferably, the barrier layer has a vapor deposited layer formed by a vapor deposition method from the viewpoint of a high barrier property thereof, and so on.

The vapor deposited layer is not particularly limited about the kind of the vapor depositing method therefor, or the like as long as the layer is a layer formed by the vapor deposition. The vapor deposition method may be a CVD method or a PVD method. When the vapor deposited layer is formed by, for example, a CVD method such as a plasma CVD, the formed layer can become a dense layer having a high barrier property. However, it is preferred to use a PVD method from the viewpoint of production efficiency, costs and others. The PVD method used in the invention maybe, for example, a vacuum vapor deposition, a sputtering or ion plating method, and particularly the vacuum vapor deposition method is preferred from the viewpoint of the barrier property of the layer formed by the method, and others. Specific examples of the vacuum vapor deposition method used in the invention include a vacuum vapor deposition method in an electron beam (EB) heating manner, and that in a high frequency induction heating manner.

The material for the vapor deposited layer is preferably a metal or an inorganic oxide. Examples thereof include Ti, Al, Mg, Zr, a silicon oxide, an aluminum oxide, a silicon oxynitride, an aluminum oxynitride, a magnesium oxide, a zinc oxide, an indium oxide, a tin oxide, an yttrium oxide, B₂O₃, and CaO. Of these, the silicon oxide is more preferred since the layer made of silicon oxide has a high barrier property and a high transparency.

The thickness of the vapor deposited layer is varied in accordance with the kind of the used material or the structure of the organic thin-film solar cell, and is preferably in a range of 5 to 1000 nm, more preferably 10 to 500 nm. If the thickness of the vapor deposited layer is smaller than this range, the layer may not easily be a uniform layer so that the above-mentioned barrier property may not be obtained. If the thickness of the vapor deposited layer is larger than the range, cracks or the like may be generated in the layer by an external factor, such as tension, after the layer is formed, so that the barrier property may be remarkably damaged. Additionally, a considerable time is required for the formation so that the productivity also falls.

As an underlying layer of the barrier layer, an anchor layer may be formed. This makes it possible to make the barrier property or the weather resistance high. Examples of the material for forming the anchor layer include adhesive resins, inorganic oxides, organic oxides, and metals.

Examples of the method for forming the anchor layer include sputtering, ion plating, and other PVD methods, CVD methods, roll coating, spin coating, and combinations thereof. Among these, in-line coating at the time of forming the layer is particularly preferable. This is excellent in mass productivity and also makes it possible to make the adhesiveness of the anchor layer high.

The protecting hard coat layer may be formed on the outermost surface of the organic thin-film solar cell in the invention. The protecting hard coat layer is a layer having ultraviolet shielding property and weather resistance, and is a layer formed to protect the organic semiconductor layer in order to protect the organic thin-film solar cell from external environment, thereby preventing a deterioration in the organic semiconductor materials contained in the organic semiconductor layer.

The material for forming the protecting hard coat layer is not particularly limited as long as the material is a material having ultraviolet shielding property and weather resistance. Examples thereof include acrylic-contained resins, fluorine-contained resins, silicone-contained resins, melamine-contained resins, polyester-contained resins, and polycarbonate-contained resins. These resins may be used alone or in combination of two or more thereof.

Alight resistant additive maybe added to the resin(s). Examples of the light resistant additive include a light stabilizer (HALS) and an ultraviolet absorbent (UVA).

The film thickness of the protecting hard coat layer is preferably in a range of 0.5 to 20 μm. If the film thickness is smaller than this range, the ultraviolet shielding property and the weather resistance may become insufficient. If the film thickness is larger than the range, coating work of the film becomes difficult so that the mass productivity may be poor.

Examples of the method for forming the protecting hard coat layer include sputtering, ion plating, and other PVD methods, CVD methods, roll coating, spin coating, and combinations thereof. Among these, roll coating is preferably used. Roll coating is excellent in mass productivity, and also makes it possible to form a protecting hard coat layer good in ultraviolet shielding property and weather resistance.

As an underlying layer of the protecting hard coat layer, an anchor layer may be formed. This makes it possible to make the weather resistance high.

Examples of the method for forming the anchor layer include sputtering, ion plating, and other PVD methods, CVD methods, roll coating, spin coating, and combinations thereof. Among these, in-line coating at the time of forming the layer is particularly preferable. This is excellent in mass productivity and also makes it possible to make the adhesiveness of the anchor layer high.

The strength supporting layer may be formed at the inner side of the protecting hard coat layer. The position where the strength supporting layer is formed may be any position as long as the position is at the inner side of the protecting hard coat layer. The strength supporting layer is preferably formed between any two of the functional layers. Alternatively, the function of the strength supporting layer may be given to the substrate itself.

The strength supporting layer is excellent in heat resistance, wet heat resistance, hydrolysis resistance, and transparency.

About the heat resistance, it is preferred that when a heat resistance test is made wherein the layer is kept at a temperature of 100° C. for 72 hours, the decreasing ratio of the power generating efficiency after the test to that before the test is 10% or less. Furthermore, it is preferred that when a heat resistance test is made wherein the layer is kept at a temperature of 125° C. for 72 hours, the decreasing ratio of the power generating efficiency after the test to that before the test is 10% or less. The heat resistance test is made in accordance with JIS C60068-2-2.

About the wet heat resistance, it is preferred that when a wet heat test is made wherein the organic thin-film solar cell is held for 96 hours or longer in a thermo-hygrostat environment the inside temperature and humidity of which are beforehand adjusted to 40° C. or higher and 90% RH or more, respectively, the decreasing ratio of the power generating efficiency after the test to that before the test is 10% or less. Furthermore, it is preferred that when a wet heat test is made wherein the organic thin-film solar cell is held for 500 hours or longer in a thermo-hygrostat environment the inside temperature and humidity of which are beforehand adjusted to 80° C. or higher and 80% RH or more, respectively, the decreasing ratio of the power generating efficiency after the test to that before the test is 10% or less. The wet heat test is made in accordance with JIS C60068-2-3, using an environment test machine “HIFLEX α series FX424P”, manufactured by Kusumoto Chemicals Ltd,.

About the transparency, the transmittance to entire rays is preferably 70% or more, more preferably 85% or more. The transmittance to entire rays is a value measured in the range of visible rays by use of an SM Color Computer (model number: SM-C) manufactured by Suga Test Instruments Co., Ltd.

This is because the organic thin-film solar cell is required to have excellent heat resistance, wet heat resistance, and transparency.

Examples of the material for forming the strength supporting layer Include a silicone-contained resin, an acrylic-contained resin, a cyclic polyolefin-contained resin, a syndiotactic polystyrene (SPS)-contained resin, a polyamide (PA)-contained resin, a polyacetal (POM)-contained resin, a modified polyphenylene ether (mPPE)-contained resin, a polyphenylene sulfide (PPS)-contained resin, a fluorine-contained resin (polytetrafluoroethylene (PTEE), an ethylene/tetrafluoroethylene copolymer (ETFE), a polychlorotrifluoroethylene (PCTFE), a fluorinated ethylene propylene (FEP)) , a polyetheretherketone (PEEK)-contained resin, a liquid crystal polymer (LCP), a polyethernitrile (PEN)-contained resin, a polysulfone (PSF)-contained resin, a polyethersulfone (PES)-contained resin, a polyarylate (PAR)-contained resin, a polyamideimide (PAI)-contained resin, a polyimide (PI)-contained resin, a polyethyleneterephthalate (PEN), a polypropylene (PP), an acrylonitrile/butadiene/styrene copolymer (ABS), a biaxially oriented polystyrene (OPS), a polyethylene terephthalate (PET), a polybutylene terephthalate (PBT), a polycarbonate (PC), a polyester (PE), and a polyacrylonitrile (PAN). These resins in a weather resistant grade can also be used. Furthermore, these resins may each be combined with glass fiber or the like to make the strength higher.

The film thickness of the strength supporting layer is preferably in a range of 10 to 800 μm, more preferably 100 to 400 μm. If the film thickness is smaller than this range, a sufficient strength may not be obtained. If the film thickness is larger than the range, the work in the production process may become difficult.

The adhesive layer may be formed between any two of the layers in accordance with the layer structure.

The adhesive layer is a layer excellent in heat resistance and wet heat resistance.

About the heat resistance, it is preferred that when a heat resistance test is made wherein the layer is kept at a temperature of 100° C. for 72 hours, the decreasing ratio of the power generating efficiency after the test to that before the test is 10% or less. Furthermore, it is preferred that when a heat resistance test is made wherein the layer is kept at a temperature of 125° C. for 72 hours, the decreasing ratio of the power generating efficiency after the test to that before the test is 10% or less.

About the wet heat resistance, it is preferred that when a wet heat test is made wherein the organic thin-film solar cell is held for 96 hours or longer in a thermo-hygrostat environment the inside temperature and humidity of which are beforehand adjusted to 40° C. or higher and 90% RH or more, respectively, the decreasing ratio of the power generating efficiency after the test to that before the test is 10% or less. Furthermore, it is preferred that when a wet heat test is made wherein the organic thin-film solar cell is held for 500 hours or longer in a thermo-hygrostat environment the inside temperature and humidity of which are beforehand adjusted to 80° C. or higher and 80% RH or more, respectively, the decreasing ratio of the power generating efficiency after the test to that before the test is 10% or less.

This is because the organic thin-film solar cell is required to have excellent heat resistance and wet heat resistance. The heat resistance test and the wet heat test are made in accordance with those mentioned above.

Examples of the material for forming the adhesive layer include a silicone-contained resin, a rubber-contained resin, an acrylic-contained resin, a polyester urethane-contained resin, a vinyl acetate-contained resin, a polyvinyl alcohol-contained resin, a phenol-contained resin, a melamine-contained resin, a hot-melt based resin, a polyurethane-contained resin, a polyolefin-contained resin, an epoxy resin, and a styrene butadiene-contained resin. These resins of a weather resistant grade can also be used.

The film thickness of the adhesive layer is preferably in a range of 1 to 200 μm, more preferably 2 to 20 μm. If the film thickness is smaller than this range, the strength maybe poor. If the film thickness is larger than the range, the work in the production process may become difficult.

Examples of the method for forming the adhesive layer include dry laminating and melting extrusion laminating methods. The adhesive layer may be laminated through an adhesive sheet. Preferably, the dry laminating method by roll coating is used. This method is excellent in mass productivity so as to give a good adhesiveness.

The organic thin-film solar cell of the invention can be manufactured by the above-mentioned organic thin-film solar cell manufacturing method. In other words, the cell can be manufactured by the above-mentioned laminated body manufacturing method.

The invention is not limited to the above-mentioned embodiments. The embodiments are illustrative, and any embodiment which has a construction which is substantially equivalent to the technical conception recited in the claims of the invention and produces similar effects is included in the technical scope of the invention.

### EXAMPLES

Hereinafter, the invention will be specifically described by way of working examples and comparative examples.

### Example 1

(Formation of a First Electrode Layer)

A SiO₂ thin film was formed on a surface of a polyethylene naphthalate (PEN) film substrate (thickness: 125 μm) by PVD. An ITO film (film thickness: 150 nm, and sheet resistance: 20 Ω/□), which was a transparent electrode, was formed on the upper surface of the SiO₂ thin film by reactive ion plating method (power: 3.7 kW, film-forming pressure: 0.3 Pa, film-forming rate: 150 nm/minute, and substrate temperature: 20° C.) using a pressure gradient type plasma gun, and then etched to be patterned. Next, the substrate, in which the ITO pattern was formed, was washed by using acetone, a substrate washing liquid, and IPA separately.

(Formation of a Hole Taking-out Layer)

A hole taking-out layer forming coating-solution (dispersion of an electroconductive polymer paste, poly(3,4)-ethylenedioxythiophene in water) was coated onto the substrate wherein the ITO pattern was formed, and then dried at 150° C. for 30 minutes to form a hole taking-out layer (film thickness: 100 nm).

(Formation of an Organic Semiconductor Layer)

Next, an electron hole transporting layer, which was a first layer and would be an underlying layer, was formed. At the ratio by weight of 3:5:2, the following were mixed: a 0.3% by weight solution of a polyalkylthiophene (P3HT; poly 3-hexylthiophene-2,5-diyl (regio-regular)) in chloroform; a 0.3% by weight solution of a polyphenylenevinylene (MDMO-PPV; poly(2-methoxy-5-(3′,7′-dimethyloctyloxy)-1-4-phenylenevinylene) (weight-average molecular weight: 1,000,000) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a first layer.

This electron hole transporting layer forming coating-solution was coated onto the hole taking-out layer by spin coating, and dried at 110° C. for 10 minutes so as to form an electron hole transporting layer (film thickness: 100 nm) which was the first layer.

A second layer-electron hole transporting layer was further formed. At the ratio by weight of 3:1, the following were mixed: a 0.3% by weight solution of a polyalkylthiophene (P3HT; poly3-hexylthiophene-2,5-diyl (regio-regular)) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a second layer.

This electron hole transporting layer forming coating-solution was coated onto the first layer-electron hole transporting layer by spin coating, and dried at 110° C. for 10 minutes so as to form an electron hole transporting layer (film thickness: 100 nm) which was the second layer.

(Formation of a Second Electrode Layer)

Next, a Ca thin film (film thickness: 100 nm) and an Al thin film (film thickness: 500 nm) were successively formed on the organic semiconductor layer by vapor deposition to form a metal electrode.

(Production of an Organic Thin-Film Solar Cell)

Lastly, the resultant was sealed up from above the metal electrode with a sealing glass material, so as to manufacture an organic thin-film solar cell of a bulk hetero-junction type.

### Example 2

(Formation of a Transparent Electrode Layer)

A SiO₂ thin film and an ITO pattern were formed on a polyethylene naphthalate (PEN) film substrate in the same way as in Example 1.

(Formation of a Hole Taking-Out Layer)

A hole taking-out layer forming coating-solution (dispersion of an electroconductive polymer paste, poly(3,4)-ethylenedioxythiophene in water) was coated onto the substrate wherein the ITO pattern was formed, and then dried at 150° C. for 30 minutes to form a hole taking-out layer (film thickness: 100 nm).

(Formation of an Organic Semiconductor Layer)

Next, an electron hole transporting layer, which was a first layer and would be an underlying layer, was formed. At the ratio by weight of 5:3, the following were mixed: a 0.3% by weight solution of a polyphenylenevinylene (MDMO-PPV; poly(2-methoxy-5-(3′,7′-dimethyloctyloxy)-1-4-phenylenevinylene) (weight-average molecular weight: 1,000,000) in chloroform; and a 0.1% by weight solution of a fullerene (PCEM; ¹-(3-methoxycarbonyl)propyl-1-phenyl (6,6)-C₆₀) in chloroform. In this way, prepared was an electron hole transporting layer forming coating-solution for a first layer.

This electron hole transporting layer forming coating-solution was coated onto the first layer-electron hole transporting layer by spin coating, and dried at 110° C. for 10 minutes so as to form an electron hole transporting layer (film thickness: 100 nm) which was the first layer.

A second layer-electron hole transporting layer was further formed. At the ratio by weight of 5:3, the following were mixed: a 0.3% by weight solution of a polyalkylthiophene (P3HT; poly 3-hexylthiophene-2,5-diyl (regio-regular)) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a second layer.

This electron hole transporting layer forming coating-solution was coated onto the first layer-electron hole transporting layer by spin coating, and dried at 110° C. for 10 minutes so as to form an electron hole transporting layer (film thickness: 100 nm) which was the second layer.

(Formation of a Second Electrode Layer)

Next, a Ca thin film (film thickness: 100 nm) and an Al thin film (film thickness: 500 nm) were successively formed on the organic semiconductor layer by vapor deposition to form a metal electrode.

(Production of an Organic Thin-Film Solar Cell)

Lastly, the resultant was sealed up from above the metal electrode with a sealing glass material, so as to manufacture an organic thin-film solar cell of a bulk hetero-junction type.

### Example 3

(Formation of a Transparent Electrode Layer)

A SiO₂ thin film and an ITO pattern were formed on a polyethylene naphthalate (PEN) film substrate in the same way as in Example 1.

(Formation of a Hole Taking-out Layer)

A hole taking-out layer forming coating-solution (dispersion of an electroconductive polymer paste, poly(3,4)-ethylenedioxythiophene in water) was coated by spin coating onto the substrate wherein the ITO pattern was formed, and then dried at 150° C. for 30 minutes to form a hole taking-out layer (film thickness: 100 nm).

(Formation of an Organic Semiconductor Layer)

Next, an electron hole transporting layer, which was a first layer and would be an underlying layer, was formed. At the ratio by weight of 3:5:2, the following were mixed: a 0.3% by weight solution of a polyalkylthiophene (P3HT; poly 3-hexylthiophene-2,5-diyl (regio-regular)) in chloroform; a 0.3% by weight solution of a polyphenylenevinylene (MDMO-PPV; poly (2-methoxy-5-(3′,7′-dimethyloctyloxy)-1-4-phenylenevinylene) (weight-average molecular weight: 1,000,000) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a first layer.

This electron hole transporting layer forming coating-solution was coated onto the hole taking-out layer by spin coating, and dried at 110° C. for 10 minutes so as to form an electron hole transporting layer (film thickness: 100 nm) which was the first layer.

A second layer-electron hole transporting layer was further formed. At the ratio by weight of 3:5:2, the following were mixed: a 0.3% by weight solution of a polyalkylthiophene (P3HT; poly 3-hexylthiophene-2,5-diyl (regio-regular)) in chloroform; a 0.3% by weight solution of a polyphenylenevinylene (MDMO-PPV; poly(2-methoxy-5-(3′,7′-dimethyloctyloxy)-1-4-phenylenevinylene) (weight-average molecular weight: 1,000,000) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a second layer.

This electron hole transporting layer forming coating-solution was coated onto the first layer-electron hole transporting layer by spin coating, and dried at 110° C. for 10 minutes so as to form an electron hole transporting layer (film thickness: 100 nm) which was the second layer.

A third layer-electron hole transporting layer was formed. At the ratio by weight of 1:1, the following were mixed: a 0.1% by weight solution of polyfluorene in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution for a third layer.

This electron hole transporting layer forming coating-solution was coated onto the second layer-electron hole transporting layer by spin coating, and dried at 110° C. for 10 minutes so as to form an electron hole transporting layer (film thickness: 100 nm) which was the third layer.

(Formation of a Metal Electrode)

Next, a Ca thin film (film thickness: 100 nm) and an Al thin film (film thickness: 500 nm) were successively formed on the third layer-electron hole transporting layer by vapor deposition to form a metal electrode.

(Production of an Organic Thin-Film Solar Cell)

Lastly, the resultant was sealed up from above the metal electrode with a sealing glass material, so as to manufacture an organic thin-film solar cell of a bulk hetero-junction type.

### Example 4

(Formation of a Transparent Electrode Layer)

A SiO₂ thin film and an ITO pattern were formed on a polyethylene naphthalate (PEN) film substrate in the same way as in Example 1.

(Formation of a Hole Taking-Out Layer)

A hole taking-out layer forming coating-solution (dispersion of an electroconductive polymer paste, poly(3,4)-ethylenedioxythiophene in water) was coated by spin coating onto the substrate wherein the ITO pattern was formed, and then dried at 150° C. for 30 minutes to form a hole taking-out layer (film thickness: 100 nm),

(Formation of an Organic Semiconductor Layer)

Next, a first layer-hole transporting layer as to be an underlying later was formed. A polyphenylenevinylene (MDMO-PPv; poly(2-methoxy-5-(3′,7′-dimethyloctyloxy)-1-4-phenylenevinylene) (weight-average molecular weight: 1,000,000) was dissolved into a solvent of chloroform, so as to give a concentration of 0.3% by weight, thereby preparing a hole transporting layer forming coating-solution. This hole transporting layer forming coating-solution was coated onto the hole taking-out layer by spin coating, and dried at 110° C. for 10 minutes so as to form an hole transporting layer (film thickness: 100 nm).

A second-layer electron hole transporting layer was formed. At the ratio by weight of 3:1, the following were mixed: a 0.3% by weight solution of a polyalkylthiophene (P3HT; poly3-hexylthiophene-2,5-diyl (regio-regular)) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution.

This electron hole transporting layer forming coating-solution was coated onto the hole transporting layer by spin coating, and dried at 110° C. for 10 minutes so as to form an electron hole transporting layer (film thickness: 100 nm).

(Formation of a Metal Electrode)

Next, a Ca thin film (film thickness: 100 nm) and an Al thin film (film thickness: 500 nm) were successively formed on the electron hole transporting layer by vapor deposition to form a metal electrode.

(Production of an Organic Thin-film Solar Cell)

Lastly, the resultant was sealed up from above the metal electrode with a sealing glass material, so as to manufacture an organic thin-film solar cell of a bulk hetero-junction type.

### Example 5

(Formation of a Transparent Electrode Layer)

A SiO₂ thin film and an ITO pattern were formed on a polyethylene naphthalate (PEN) film substrate in the same way as in Example 1.

(Formation of a Hole Taking-Out Layer)

A hole taking-out layer forming coating-solution (a dispersion of an electroconductive polymer paste, poly(3,4)-ethylenedioxythiophene in water) was coated by spin coating onto the substrate, wherein the ITO pattern was formed, and dried at 150° C. for 30 minutes to form a hole taking-out layer (film thickness: 100 nm).

(Formation of an Organic Semiconductor Layer)

Next, a first layer-electron hole transporting layer as to be an underlying later was formed. At the ratio by weight of 3:5:2, the following were mixed: a 0.3% by weight solution of a polyalkylthiophene (P3HT; poly 3-hexylthiophene-2,5-diyl (regio-regular)) in chloroform; a 0.3t by weight solution of a polyphenylenevinylene (MDMO-PPV; poly(2-methoxy-5-(3′,7′-dimethyloctyloxy)-1-4-phenylenevinylene) (weight-average molecular weight: 1,000,000) in chloroform; and a 0.1% by weight solution of a fullerene (PCBM; 1-(3-methoxycarbonyl)propyl-1-phenyl (6,6)-C₆₀) in chloroform. In this way, prepared was an electron hole transporting layer forming coating-solution.

This electron hole transporting layer forming coating-solution was coated onto the hole taking-out layer by spin coating, and dried at 110° C. for 10 minutes so as to form an electron hole transporting layer (film thickness: 100 nm).

A second layer-electron transporting layer was formed further. A polyfluorene was dissolved into a solvent of chloroform, so as to give a concentration of 0.1% by weight, thereby preparing an electron transporting layer forming coating-solution. This electron transporting layer forming coating-solution was coated onto the electron hole transporting layer by spin coating, and dried at 110° C. for 10 minutes so as to form an electron transporting layer (film thickness: 100 nm).

(Formation of a Metal Electrode)

Next, a Ca thin film (film thickness: 100 nm) and an Al thin film (film thickness: 500 nm) were successively formed on the electron transporting layer by vapor deposition to form a metal electrode.

(Production of an Organic Thin-Film Solar Cell)

Lastly, the resultant was sealed up from above the metal electrode with a sealing glass material, so as to manufacture an organic thin-film solar cell of a bulk hetero-junction type.

### Example 6

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed; a 0.1% by weight solution of a fullerene (PCBM) in chloroform, and a 0.3% by weight solution of a polyalkylthiophene (P3HT: poly3-hexylthiophene-2,5-diyl (regio-regular)) (weight-average molecular weight: 500,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a polyalkylthiophene (P3HT: poly-3-hexylthiophene-2,5-diyl (regio-regular)) (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second electron hole transporting layer by spin coating, and then dried at 110° C. for 10 minutes to form the electron hole transporting layer which was the third layer (film thickness: 30 nm)

### Example 7

An organic thin-film solar cell was manufactured in the same way as in Example 1 except that its organic semiconductor layer was formed as follows.

(Formation of the Organic Semiconductor Layer)

Next, an electron hole transporting layer that was a first layer and would be an underlying layer, was formed as follows. At the ratio by weight of 3:5:2, the following were mixed: a 0 3% by weight solution of polyalkylthiophene (P3HT) in chloroform, a 0.1% by weight solution of a fullerene (PCBM) in chloroform, and a 0.3% by weight solution of a thiophene-fluorene copolymer (poly[(9,9-dihexylfluorenyl-2,7-diyl)-co-(bithiophene)]) (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Further, an electron hole transporting layer that was a second layer was formed as follows. At the ratio by weight of 3:5:2, the following were mixed: a 0.3% by weight solution of polyalkylthiophene (P3HT) in chloroform, a 0.1% by weight solution of a fullerene (PCBM) in chloroform, and a 0.3% by weight solution of a thiophene-fluorene copolymer (poly[(9,9-dihexylfluorenyl-2,7-diyl)-co-(bithiophene)]) (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first electron hole transporting layer by spin coating, and then dried at 110° C. for 10 minutes to form the electron hole transporting layer which was the second layer (film thickness: 30 nm).

Further, an electron hole transporting layer that was a third layer was formed as follows. At the ratio by weight of 1:1, the following were mixed: a 0.3% by weight solution of polyalkylthiophene (P3HT) in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm)

### Example 8

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a thiophene-fluorene copolymer (poly[(9,9-dihexylfluorenyl-2,7-diyl)-co-(bithiophene)]) (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed; a 0.1% by weight solution of polyfluorene in chloroform, a 0.1% by weight solution of a fullerene (PCBM) in chloroform, and a 0.3% by weight solution of a thiophene-fluorene copolymer (poly[(9,9-dihexylfluorenyl-2,7-diyl)-co-(bithiophene)]) (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.3% by weight solution of polyalkylthiophene (P3HT) in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

### Example 9

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 5:2, the following were mixed: a 0.1% by weight solution of a fullerene (PCBM) in chloroform, and a 0.3% by weight solution of a phenyleneethynylene-phenylenevinylene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second electron hole transporting layer by spin coating, and then dried at 110° C. for 10 minutes o form the electron hole transporting layer which was the third layer (film thickness: 30 nm).

The used phenyleneethynylene-phenylenevinylene copolymer was illustrated by the following formula:

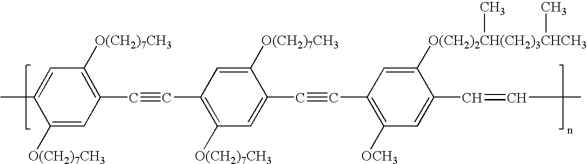

### Example 10

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a phenyleneethynylene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-phenylenevinylene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The phenyleneethynylene-phenylenevinylene copolymer used was the same as the above-mentioned formula.

### Example 11

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-thiophene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-thiophene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The used phenyleneethynylene-thiophene copolymer was illustrated by the following formula:

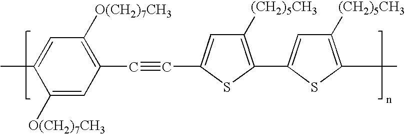

### Example 12

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a phenyleneethynylene-thiophene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.1% by weight solution of polyfluorene in chloroform, a 0.1% by weight solution of a fullerene (PCBM) in chloroform, and a 0.3% by weight solution of a phenyleneethynylene-thiophene copolymer (weight-average molecular weight: 1,000,000) in chloroform. This solution was filtrated with a filter paper of φ0.2 μm to prepare an electron hole transporting layer forming coating-solution for he second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.3% by weight solution of polyalkylthiophene (P3HT) in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The phenyleneethynylene-thiophene copolymer used was the above-mentioned formula.

### Example 13

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-fluorene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a phenyleneethynylene-fluorene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The used phenyleneethynylene-fluorene copolymer was illustrated by the following formula:

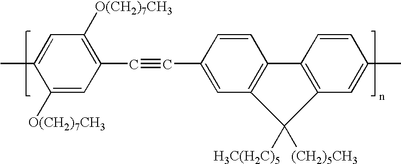

### Example 14

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a phenyleneethynylene-fluorene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer which was a second layer was formed as follows. At the ratio by weight of 5:2, the following were mixed: a 0.1% by weight solution of a fullerene (PCBM) in chloroform, and a 0.3% by weight solution of a phenyleneethynylene-fluorene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The phenyleneethynylene-fluorene copolymer used was that of the above-mentioned formula.

### Example 15

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a fluorene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a fluorene-phenylenevinylene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The used fluorene-phenylenevinylene copolymer was illustrated by the following formula:

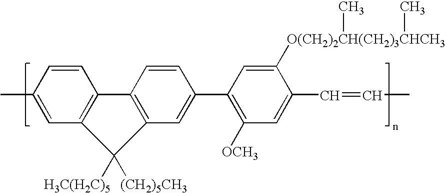

### Example 16

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a fluorene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows. At the ratio by weight of 3:5:2, the following were mixed: a 0.1% by weight solution of polyfluorene in chloroform, a 0.1% by weight solution of a fullerene (PCBM) in chloroform, and a 0.3% by weight solution of fluorene-phenylenevinylene copolymer (weigh-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form an electron hole transporting layer which was the second layer (film thickness: 30 nm).

Furthermore, an electron hole transporting layer, which was a third layer, was formed as follows. At the ratio by weight of 1:1, the following were mixed: a 0.3% by weight solution of polyalkylthiophene (P3HT) in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The fluorene-phenylenevinylene copolymer used was that of the above-mentioned formula.

### Example 17

An organic thin-film solar cell was manufactured in the same way as in Example 1 except that its organic semiconductor layer was formed as follows.

(Formation of the Organic Semiconductor Layer)

Next, an electron hole transporting layer, which was a first layer and would be an underlying layer, was formed as follows. At the ratio by weight of 3:5.2, the following were mixed: a 0.3% by weight solution of a polyalkylthiophene (P3HT) in chloroform, a 0.1% by weight solution of a fullerene (PCBM) in chloroform, and a 0.3% by weight solution of a thiophene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Furthermore, an electron hole transporting layer, which was a second layer, was formed as follows.

At the ratio by weight of 3:5:2, the following were mixed: a 0.3% by weight solution of a polyalkylthiophene (P3HT) in chloroform, a 0.1% by weight solution of a fullerene (PCBM) in chloroform, and a 0.3% by weight solution of a thiophene-phenylenevinylene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed; a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The used thiophene-phenylenevinylene copolymer was illustrated by the following formula:

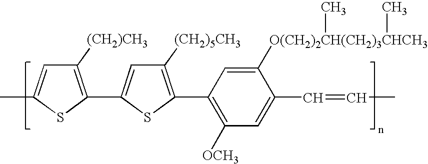

### Example 18

An organic thin-film solar cell was manufactured in the same way as in Example 1 except that its organic semiconductor layer was formed as follows.

(Formation of the Organic Semiconductor Layer)

An electron hole transporting layer, which was a first layer and would be an underlying layer, was formed as follows. At the ratio by weight of 3:5, the following were mixed: a 0.1% by weight solution of a fullerene (PCBM) in chloroform, and a 0.3% by weight solution of a thiophene-phenylenevinylene copolymer (weight-average molecular weight: 1,000,000) in chloroform. This solution was filtrated with a filter paper of φ0.2 μm to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 30 nm).

Further, an electron hole transporting layer, which was a second layer, was formed as follows. At the ratio by weight of 5:2, the following were mixed; a 0.1% by weight solution of a fullerene (PCBM) in chloroform, and a 0.3% by weight solution of a thiophene-phenylenevinylene copolymer (weight-average molecular weight: 1,000,000) in chloroform. This solution was filtrated with a filter paper of φ0.2 μm to prepare an electron hole transporting layer forming coating-solution for the second layer.

This electron hole transporting layer forming coating-solution was coated onto the first layer-electron hole transporting layer by spin coating, and then dried at 110° C. for 10 minutes to form the electron hole transporting layer which was the second layer (film thickness: 30 nm).

Furthermore, an electron hole transporting layer, which was a third layer, was formed as follows. At the ratio by weight of 1:1, the following were mixed: a 0.1% by weight solution of polyfluorene in chloroform, and a 0.1% by weight solution of a fullerene (PCBM) in chloroform. This solution was filtrated with a filter paper of φ0.2 μm to prepare an electron hole transporting layer forming coating-solution for the third layer.

This electron hole transporting layer forming coating-solution was coated onto the second layer-electron hole transporting layer by spin coating, and then dried at 110° C. for 10 minutes to form the electron hole transporting layer which was the third layer (film thickness: 30 nm).

The thiophene-phenylenevinylene copolymer used was that of the above-mentioned formula.

### Comparative Example

The same manner as in Example 1 was performed except that an organic semiconductor layer was formed as follows.

(Formation of an Organic Semiconductor Layer)

An electron hole transporting layer, which was a first layer and would be an underlying layer, was formed as follows. At the ratio by weight of 3:1, the following were mixed: a 0.3% by weight solution of a polyalkylthiophene (P3HT: poly 3-hexylthiophene-2,5-diyl (regio-regular)) (weight-average molecular weight: 80,000) in chloroform, and a 0.1% by weight solution of a fullerene (PCBM: 1-(3-methoxycarbonyl)propyl-1-phenyl (6,6)-C₆₀) in chloroform, so as to prepare an electron hole transporting layer forming coating-solution for the first layer.

This electron hole transporting layer forming coating-solution was coated onto the hole taking-out layer by spin coating, and then dried at 110° C. for 10 minutes to form the electron hole transporting layer which was the first layer (film thickness: 100 nm).

Furthermore, an electron hole transporting layer, which was a second layer, was formed as follows. At the ratio by weight of 3:1, the following were mixed: a 0.3% by weight solution of a polyalkylthiophene (P3HT: poly 3-hexylthiophene-2,5-diyl (regio-regular)) in chloroform, and a 0.1% by weight solution of a fullerene (PCBM: 1-(3-methoxycarbonyl)propyl-1-phenyl (6,6)-C₆₀) in chloroform, so as to prepare an electron hole transporting layer forming coating-solution for the second layer.

This electron hole transporting layer forming coating-solution was coated onto the first layer-electron hole transporting layer by spin coating. As a result, the first layer-electron hole transporting layer, which was an underlying layer, was dissolved, so that no element was manufactured and no cell performance was expressed.

What is claimed is:

1. A manufacturing method of a laminated body, comprising an underlying layer forming step of coating an underlying layer forming coating-solution comprising a polymer material to form an underlying layer, and an upper layer forming step of coating an upper layer forming coating-solution on the underlying layer to form an upper layer.

2. The manufacturing method of a laminated body according to claim 1, wherein a weight-average molecular weight of the polymer material is 100,000 or more.

3. The manufacturing method of a laminated body according to claim 1, wherein a solvent in the upper layer forming coating solution has compatibility with a solvent in the underlying layer forming coating-solution.

4. The manufacturing method of a laminated body according to claim 1, wherein the polymer material is a high molecular organic semiconductor material and the upper layer forming coating-solution comprises the high molecular organic semiconductor material.

5. The manufacturing method of a laminated body according to claim 4, wherein the high molecular organic semiconductor material is an electroconductive polymer material.

6. A manufacturing method of an organic device comprising a substrate, a first electrode layer formed on the substrate, an organic semiconductor layer formed on the first electrode layer and comprising at least two organic layers, and a second electrode layer formed on the organic semiconductor layer,
wherein the manufacturing method of a laminated body according to claim 1 is used to form the organic semiconductor layer.

7. A manufacturing method of an organic thin-film solar cell, using the manufacturing method of an organic device according to claim 6,
wherein the organic semiconductor layer of the organic device has the two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.

8. An organic device, comprising a substrate, a first electrode layer formed on the substrate, an organic semiconductor layer formed on the first electrode layer and comprising a first organic layer comprising a high molecular organic semiconductor material having a weight-average molecular weight of 100,000 or more and a second organic layer formed on the first organic layer, and a second electrode layer formed on the organic semiconductor layer.

9. An organic thin-film solar cell comprising the organic device according to claim 8,
wherein the organic semiconductor layer of the organic device has two or more organic layers selected from the group consisting of a plurality of electron hole transporting layers each comprising a p type organic semiconductor material and an n type organic semiconductor material, a plurality of hole transporting layers each comprising a p type organic semiconductor material, and a plurality of electron transporting layers each comprising an n type organic semiconductor material.
